(19) United States
(12) Patent Application Publication
(10) Pub. No.: US 2023/0377895 A1
(43) Pub. Date: Nov. 23, 2023

(54) PLASMA ETCHING USING MULTIPHASE MULTIFREQUENCY POWER PULSES AND VARIABLE DUTY CYCLING

(71) Applicant: Tokyo Electron Limited, Tokyo (JP)

(72) Inventors: Ya-Ming Chen, Austin, TX (US); Shyam Sridhar, Austin, TX (US); Peter Lowell George Ventzek, Austin, TX (US); Alok Ranjan, Austin, TX (US)

(21) Appl. No.: 17/842,501

(22) Filed: Jun. 16, 2022

Related U.S. Application Data
(60) Provisional application No. 63/344,600, filed on May 22, 2022.

(51) Int. Cl. H01L 21/3065; H01J 37/32; H01L 21/02

(52) U.S. Cl. CPC H01L 21/3065; H01J 37/32091; H01J 37/3244; H01J 37/32174; H01L 21/02274

(57) ABSTRACT

In certain embodiments, a method includes positioning a substrate on a substrate holder in a processing chamber and etching the substrate by cyclically performing a periodic plasma process that includes multiple multiphase pulse cycles that each includes elevated etching, etching-and-deposition, and elevated deposition phases. The elevated deposition phase includes applying a source power (SP) to the chamber at a first SP level. The etching-and-deposition phase includes applying the SP to the chamber at a second SP level and applying a lower-frequency radio frequency (RF) bias power (LBP) to the chamber at an LBP level. The elevated deposition phase includes applying the SP to the chamber at a third SP level and applying a higher-frequency RF bias power (HBP) to the chamber at an HBP level, the third SP level being less than the first SP level. A same gas combination is supplied to the processing chamber during each cycle.

### CROSS-REFERENCE TO RELATED APPLICATIONS

This application claims the benefit of U.S. Provisional Application No. 63/344,600, filed on May 22, 2022, which is incorporated by reference.

### TECHNICAL FIELD

This disclosure relates generally to semiconductor fabrication, and, in particular embodiments, to plasma etching using multiphase multifrequency power pulses and variable duty cycling.

### BACKGROUND

Device formation within microelectronic workpieces typically involves a series of manufacturing techniques related to the formation, patterning, and removal of layers of material on a substrate. To meet the physical and electrical specifications of current and next generation semiconductor devices, process flows are being requested to reduce feature size and increase the packing density of components while maintaining structural integrity, including minimizing defects, for various patterning processes. Problems associated with such defects in the features being formed may be amplified at smaller technology nodes.

Three-dimensional (3D) structures are becoming common formations on microelectronic workpieces to increase device density. Examples of such 3D structures include fin field-effect transistors (FINFETs), gate-all-around (GAA) FETs, 3D memory structures, and other 3D structures. As the density requirements increase, however, improvements are needed to reduce production costs and to maintain device integrity and performance in 3D structures.

### SUMMARY

In certain embodiments, a method includes positioning a substrate on a substrate holder in a processing chamber and etching the substrate by cyclically performing a periodic plasma process that includes multiple multiphase pulse cycles that each includes an elevated etching phase, an etching-and-deposition phase, and an elevated deposition phase. The elevated deposition phase includes applying a source power (SP) to the processing chamber at a first SP level. The etching-and-deposition phase includes applying the SP to the processing chamber at a second SP level and applying a lower-frequency radio frequency (RF) bias power (LBP) to the processing chamber at a first LBP level. The elevated deposition phase includes applying the SP to the processing chamber at a third SP level and applying a higher-frequency RF bias power (HBP) to the processing chamber at a first HBP level, the third SP level being less than the first SP level. A same gas combination may be supplied to the processing chamber during each multiphase pulse cycle of the multiple multiphase pulse cycles.

In certain embodiments, a method includes positioning a substrate on a substrate holder in a processing chamber and etching the substrate by cyclically performing a periodic plasma process. The periodic plasma process includes applying, in a first phase, a first SP pulse to an SP coupling element to generate plasma within the processing chamber while applying a first HBP pulse to the substrate holder to etch the substrate. An RF of the first SP pulse is greater than an RF of the first HBP pulse. The periodic plasma process includes applying, in a second phase, an LBP pulse to the substrate holder, the LBP pulse being coupled to the substrate holder while applying a second SP pulse to the SP coupling element and without coupling an HBP pulse to the substrate holder to concurrently etch the substrate and deposit passivating species on the substrate. An RF of the LBP pulse is less than an RF of the first HBP pulse. The periodic plasma process includes applying, in a third phase, a second HBP pulse to the substrate holder while applying a third SP pulse to the SP coupling element to deposit passivating species on the substrate. An RF of the second HBP pulse is greater than the RF of the LBP pulse, and a power level of the third SP pulse is less than a power level of the first SP pulse and less than a power level of the second SP pulse.

In certain embodiments, a method includes positioning a semiconductor substrate in a processing chamber of a plasma tool. The semiconductor substrate includes a film stack having first layers of a first material and second layers of a second material in an alternating stacked arrangement. The film stack includes a recess that exposes sidewall surfaces of the first and second layers in the recess, and an inner spacer structure is located on the sidewall surfaces of the first and second layers and on a bottom surface of the recess. The method includes etching the inner spacer structure by cyclically performing a periodic plasma process that comprises multiple multiphase pulse cycles. Each multiphase pulse cycle includes generating, in a first phase, a plasma by applying an SP to the processing chamber, the plasma etching the inner spacer structure at a first etch rate; generating, in a second phase, low-energy ions by concurrently applying the SP and an LBP to the processing chamber, the plasma etching the inner spacer structure at a second etch rate while the low-energy ions passivate on exposed surfaces of the film stack; and generating, in a third phase, high-energy ions by concurrently applying the SP and an HBP to the processing chamber, the high-energy ions passivating on the bottom surface of the recess. A same gas combination may be supplied to the processing chamber during each multiphase pulse cycle of the multiple multiphase pulse cycles.

### BRIEF DESCRIPTION OF THE DRAWINGS

For a more complete understanding of the present disclosure, and advantages thereof, reference is now made to the following descriptions taken in conjunction with the accompanying drawings, in which:

FIG. 1 illustrates a schematic timing diagram and corresponding substrate undergoing processing of an example plasma processing method, according to certain embodiments;

FIG. 2 illustrates a schematic timing diagram and corresponding substrate undergoing processing of another example plasma processing method, according to certain embodiments;

FIG. 3 illustrates a schematic diagram of an example plasma processing apparatus, according to certain embodiments;

FIG. 4 illustrates an example method of plasma processing, according to certain embodiments;

FIG. 5 illustrates an example method of plasma processing, according to certain embodiments; and

FIG. 6 illustrates an example method of plasma processing, according to certain embodiments.

### DETAILED DESCRIPTION OF ILLUSTRATIVE EMBODIMENTS

The integrated circuit (IC) manufacturing industry strives to increase device density to improve speed, performance, and costs. For continued scaling to smaller node sizes, device architectures have evolved from two-dimensional (2D) planar structures to 3D vertical structures, such as with nanowires, nanosheets, or vertically oriented transistors. Insufficient control of the conducting channel by the gate potential drives a desire for this change. Short channel effects (SCE) may become too significant as gate dimensions are scaled down and may increase current conduction when no voltage is applied to the gate (IA. A change in device architecture may allow better electrostatic control of the gate to reduce the SCE and power loss. Fabricating nanowire/nanosheet devices may present 3D etch challenges to avoid damage to delicate nanostructures (e.g., nanowires or nanosheets) and unintended removal of material during an etch process.

Fabricating nanowire/nanosheet devices includes forming a substrate that has a film stack of layers of different materials in an alternating stacked arrangement, some of which ultimately may serve as the nanowire/nanosheets of a device and some of which may be sacrificial. In some cases, these film stacks have many layers of silicon and germanium-containing materials (e.g., silicon-germanium (SiGe)), or other suitable materials, resulting in a relatively tall film stack. Furthermore, during processing, recesses may be etched into the film stack, and these recesses may be etched essentially the full height of the film stack. Given the height of the film stack, these recesses can be very deep. Although this disclosure primarily describes “recesses,” it will be appreciated that other suitable features might be formed in a film stack or other semiconductor workpiece, including (whether or not considered “recesses”) lines, holes, trenches, vias, and/or other suitable structures, using embodiments of this disclosure.

As an example, a recess formed in one or more layers during one or more etch processes may have a high aspect ratio in which the depth of the recess is significantly greater than a width of the recess. As a particular example, an organic layer (e.g., an amorphous carbon layer (ACL)) may be used as an etch mask in forming a recess (e.g., a contact hole). Prior to the organic layer being used as an etch mask, an overlying hard mask layer may be used as an etch mask to pattern recesses in the organic layer, and the depth of these recesses may be greater than the width of these recesses, possibly significantly.

Furthermore, an inner spacer structure may be formed in the recess, both along sidewalls of the film stack in the recesses and at a bottom of the recess on what will be referred to as a bottom surface of the recess. Thus, these inner spacer structures might be formed in recesses that have a high aspect ratio. The aspect ratio of a feature generally refers to the ratio of two-dimensions of the feature (e.g., height (or depth) vs. width). A high aspect ratio may describe a structure in which one dimension is significantly larger than the other dimension. As a particular example, features having a depth that is significantly greater than a width of the feature are frequently formed in layers of a semiconductor device.

In 3D structures that include a nanowire or nanosheet film stack, an intermediate processing stage may include depositing removing some or all of the inner spacer structure from a portion of the recess (from sidewall surface of the film stack in a recess) while leaving a some or all of the inner space structure relatively unetched (e.g., the inner spacer on the bottom surface of the recess), a process sometimes referred to as trimming the inner spacer.

In a conventional inner spacer trimming process of nanowire/nanosheet structures, to adequately (partially or fully) remove the inner spacer substantially evenly from top to bottom along a sidewall in a recess of the film stack, high-energy ion and radical fluxes are used. For example, conventional inner spacer trimming techniques in nanowire/nanosheet devices may include multiple distinct deposition and etching steps that might be performed repeatedly. As a particular example, a conventional process may consist of separate chemical vapor deposition (CVD), lateral etching, and vertical etching steps for trimming an inner spacer in a nanodevice. These processes are difficult to control and add complexity to process development, and performing these distinct steps repeatedly only compounds the associated problems.

The high-energy fluxes associated with these distinctly-applied deposition and etch steps can cause damage, and potentially significant damage, to the bottom and potentially other portions of the spacer or film stack. For example, the high-energy fluxes can cause ion scattering (scattered ion flux), which can lead to bowing at the tops of film stacks, corner erosion (especially for recesses that have a high aspect ratio) at the top of the film stack and/or at edges of the nanowires/nanosheets, removal of the inner spacer at the bottom of the recess, and other problems. Among other consequences, these problems can undesirably change the critical dimension of the recess or other features of the semiconductor substrate being processed.

Plasma processing techniques, such as reactive ion etching, plasma-enhanced CVD, plasma-enhanced atomic layer etch and deposition, sputter etch, physical vapor deposition, and cyclic plasma processing (e.g., alternating deposition and etch cycles) are used in fabricating microelectronic workpieces (e.g., ICs). For example, plasma etching and plasma deposition may be used during semiconductor to form circuit elements (e.g., contact holes, nanowires/nanosheets, metal lines, fins, gate lines, vias, or other elements) by removing one or more layers of a semiconductor device. A combination of SP applied to a coupling element and bias power (BP) applied to a substrate holder may be used to generate and direct plasma. Various conditions during a plasma process may influence whether material is being deposited onto a substrate, etched from the substrate, or a combination of the two.

Conventional plasma processes fail to independently control etching and deposition during plasma processes, resulting in reduced control and precision of the processes. Taking etch processes as an example, some deposition can be useful to protect features that are not the target of the etch. But because conventional plasma processes lack independent and precise control over both deposition and etching, these features are insufficiently protected. Thus, material is undesirably removed from the features causing imperfections in feature profile, such as recesses in the tops of features and necking, among others. Therefore, plasma processing methods that provide independent control over deposition and etching may be desirable.

Both the SP and BP may be supplied as RF power to a plasma processing chamber of a plasma tool. Pulsed plasma processing techniques supply one or both of the RF SP and RF BP to a processing chamber as pulses rather than as continuous wave power. For example, BP pulses may be provided synchronously or asynchronously with SP pulses. Such existing synchronous/asynchronous schemes often use a single RF frequency for the BP, even when supplying the BP asynchronously (e.g. single frequency, dual-phase), and are not adequate to independently control etching and deposition.

Certain embodiments of this disclosure provide a multiphase, multifrequency periodic plasma process, which may include duty ramping of phases and power modulation. In certain embodiments, lateral and vertical etching can be controlled by ramping up duty cycles of SP and BP. That is, vertical etching, deposition, and lateral etching can be modulated in a time-modulated, cyclic process by ramping duty cycles of SP and BP separately, which may reduce or eliminate damage to the portions of the substrate being etched (e.g., to the inner spacer structure). Monoculture pulse schemes are inadequate to control the balance between etching and deposition with increasing time. The process may be executed using a high-density plasma reactor or other suitable plasma tool, and in certain embodiments may be performed without removing the semiconductor substrate from a plasma chamber of the plasma tool.

In certain embodiments, a multifrequency, multiphase periodic plasma process is applied to a semiconductor substrate, which also may be referred to as a wafer, a semiconductor wafer, a workpiece, a semiconductor workpiece, or the like, in a processing chamber of a plasma tool. The multifrequency, multiphase periodic plasma process may include, for each of multiple pulse cycles, a first phase, a second phase, and a third phase. The first phase may be an elevated etch phase, the second phase may be an etch-and-deposition phase, and the third phase may be an elevated deposition phase.

An appropriate selection of SP pulses and RF frequencies for bias pulses, along with associated power levels for each, may be used at each phase, to provide enhanced control over etching and deposition. For example, to achieve an elevated etch phase, an SP pulse with a high power level may be used, potentially in combination with an HBP pulse at a relatively low power level, which may facilitate radical etching. As another example, to achieve an etch-and-deposition phase, an SP pulse with a high power level may be used in combination with an LBP pulse at a moderate power level, which may facilitate controlled deposition of passivating species. As another example, to achieve an elevated deposition phase, an SP pulse with a reduced power level (relative to the first and second phases) may be used in combination with an HBP pulse at a moderate power level, which may facilitate generating high energy ions directed at a bottom surface of a target structure.

The multi-phase pulse cycles may be repeated until a desired result is achieved. In certain embodiments, a gas combination supplied to the processing chamber of a plasma tool during each cycle may remain the same. Respective duty cycles of the first phase, the second phase, and the third phase may be adjusted for each cycle, as appropriate, providing fine-tuned control over etching and deposition to facilitated accomplishing the desired result. Additionally or alternatively, one or more other plasma process parameters may be adjusted from pulse cycle-to-pulse cycle to control deposition and etch.

One application of these techniques includes etching of 3D semiconductor structures. For example, a particular application includes etching, in a high-density plasma reactor or other suitable plasma tool, an inner spacer formed in a nanosheet/nanowire structure. Certain embodiments provide for dry trimming of inner spacers in nanosheet devices using duty ramped, power-modulated plasmas. Vertical etching, deposition, and lateral etching may be controlled in a time-modulated, cyclic process by ramping duty cycles of SP and BP separately, which may reduce or eliminate damage to the spacer and/or the film stack.

In certain embodiments, a combination of multi-frequency and multiphase pulsing schemes is used to control the balance between etching and deposition. Embodiments provide greater control over the etch process to gradually etch desired portions of the inner spacer (e.g., some or all of the portions on the sidewalls of the film stack in the recess) in a way that reduces or eliminates defects in adjacent structures and, if desired, preserves desired portions of the inner spacer (e.g., a portion of the inner spacer at the bottom of the recess).

In certain embodiments, a method includes positioning a substrate on a substrate holder in a processing chamber of a plasma processing tool. In one example, the substrate may include a film stack of first layers of a first material and second layers of a second material arranged in an alternating stack with a vertical recess formed in the stack and an inner spacer structure located on sidewall surfaces of the film stack in the vertical recess and at a bottom surface of the vertical recess. The method includes etching the substrate by cyclically performing a periodic plasma process that comprises multiple multiphase pulse cycles. In this example, each multiphase pulse cycle includes a first phase, a second phase, and a third phase. A same gas combination may be supplied to the processing chamber during each phase of a pulse cycle and/or during each multiphase pulse cycle of the multiple multiphase pulse cycles.

As one example, the first phase (e.g., an elevated etching phase) may include applying an SP to the processing chamber at a first SP level, which may facilitate etching of the inner spacer structure, potentially isotropically. In one implementation a higher-frequency RF BP (HBP) is applied to the processing chamber at a first HBP level during the first phase to direct an etch species to the sidewalls of the film stack in the recess to promote etching of the inner spacer structure on the sidewalls and provide some reduced amount of etching for inner spacer structure on a surface at the bottom of the vertical recess.

As one example, the second phase (an etching-and-deposition phase) may include applying the SP to the processing chamber at a second SP level and applying a lower-frequency RF BP (LBP) to the processing chamber at a first LBP level, which may promote both lateral etching of the inner spacer and deposition of a passivation layer.

As one example, the third phase (an elevated deposition phase) may include applying the SP to the processing chamber at a third SP level and applying an HBP to the processing chamber at a second HBP level. The third SP level may be less than the first SP level, and the second HBP level may be greater than the first HBP level (to the extent an HBP is applied during the first phase. The third phase may promote elevated deposition of the passivation layer, particularly on the surface at the bottom of the vertical recess.

For different instances of a pulse cycle, one or more processing parameters may be adjusted, including potentially a power level of one or more of the SP pulse, an LBP pulse, or an HBP pulse relative to another instance of that pulse in a corresponding phase of another pulse cycle; a duty cycle of the first phase, the second phase, or the third phase; a duration of the first phase, the second phase, or the third phase; a number of phases (e.g., one or more phases could be omitted); and/or an execution order of the first phase, the second phase, and the third phase. The ability to control etching (including direction of the etching, such as lateral or vertical) and deposition (e.g., of protective substances) by adjusting power levels of applied power (SP and two frequency levels of BP), duty cycles, and other parameters provides a highly controllable process that can be tailored to etching particular structures having unique and/or challenging properties (e.g., a high aspect ratio).

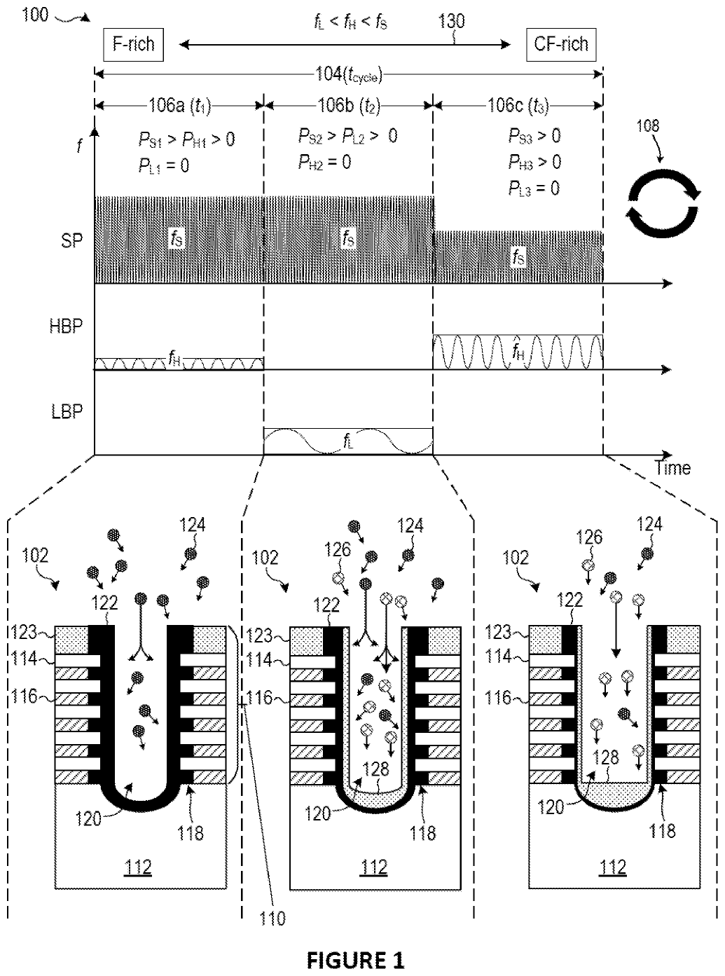

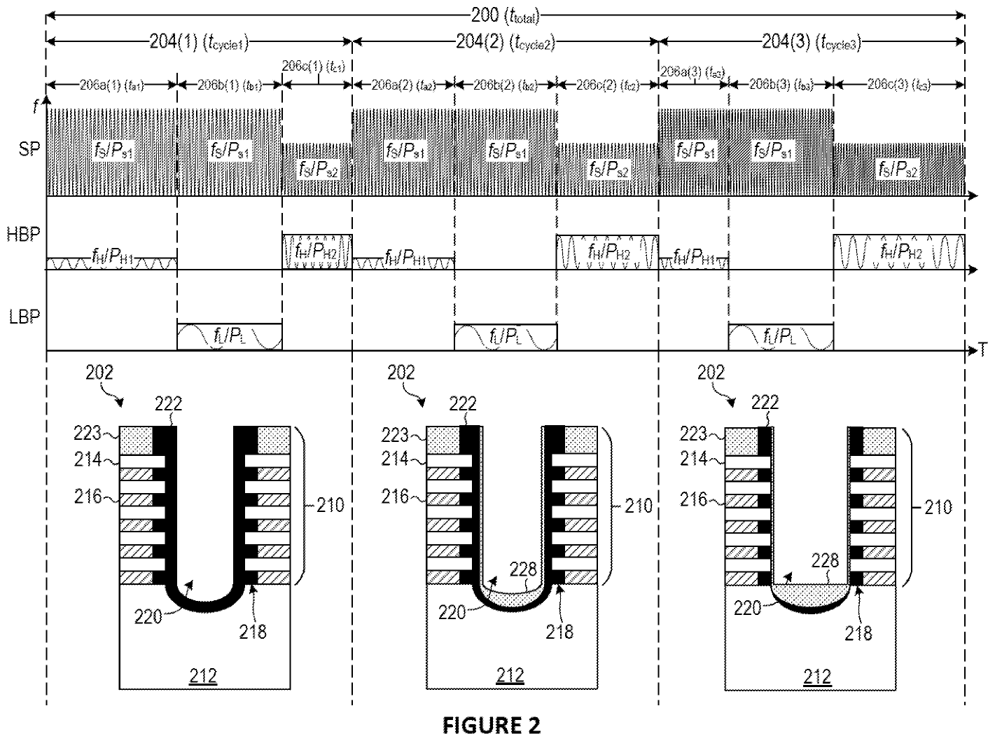

FIG. 1 illustrates a schematic timing diagram and corresponding substrate 102 undergoing processing of an example plasma processing method, according to certain embodiments. In particular, FIG. 1 illustrates one pulse cycle 104 of a periodic plasma process 100 for etching substrate 102. Periodic plasma process 100 includes multiple multiphase pulse cycles. That is, as described in greater detail below with reference to FIG. 2, the pulse cycle 104 may be repeated (executed cyclically), with one or more adjustments being made to certain plasma process parameters, if appropriate, from one pulse cycle 104 to the next.

In the illustrated example, pulse cycle 104 includes three phases, phases 106a, 106b, and 106c, which may be referred to generally as phases 106. Although pulse cycle 104 is shown to have a particular number of phases 106, this disclosure contemplates pulse cycle 104 having any suitable number of phases 106 greater than or equal to two.

During phase 106a, an SP pulse with an RF frequency f_{S} is applied concurrently with a BP pulse that is an HBP pulse having an RF frequency f_{H}. Power levels of pulses are indicated by the relative thicknesses (or heights) of the bars used to represent each pulse. For example, in phase 106a a power level Pₛ₁ of the SP pulse is greater than a power level P_{H1} of the concurrently-applied HBP pulse, both of which are greater than zero (e.g., watts). In this example, no LBP pulse is applied during phase 106a, so a power level P_{L1} of the LBP pulse is shown as zero.

During phase 106b, an SP pulse with an RF frequency f_{S} is applied concurrently with a BP pulse that is an LBP pulse having an RF frequency f_{L}. In this example, the power level Pₛ₂ of the SP pulse of phase 106b is about the same as the power level Pₛ₁ of the SP pulse of phase 106a, and power level Pₛ₂ exceeds the power level P_{L2} of the LBP pulse of phase 106b, both of which are greater than zero. In this example, no HBP pulse is applied during phase 106b, so a power level P_{H2} of the HBP pulse is shown as zero.

During phase 106c, an SP pulse with an RF frequency f_{S} is applied concurrently with a BP pulse that is an HBP pulse having an RF frequency f_{H}. In this example, the power level Pₛ₃ of the SP pulse of phase 106c is less than power level Pₛ₁ or power level Pₛ₂, and power level Pₛ₃ exceeds the power level P_{H3} of the HBP pulse of phase 106c. Additionally, power level P_{H3} exceeds power level P_{H1}. In this example, no LBP pulse is applied during phase 106c, so a power level P_{L3} of the LBP pulse is shown as zero.

The LBP pulse frequency f_{L} is less than the HBP pulse frequency f_{H}. In certain embodiments, the LBP pulse frequency f_{L} is less than about 2 MHz. For example, f_{L} may be between about 0.4 to about 2 MHz, but lower frequencies are possible. In certain embodiments, the LBP pulse frequency f_{L} is about 1.2 MHz.

In certain embodiments, the HBP pulse frequency f_{H} is greater than about 3 MHz. For example, f_{H} may be in the high frequency (HF) band of the electromagnetic spectrum ranging from 3 MHz to 30 MHz. However, the HBP pulse frequency f_{H} may also be higher, such as in the very-high frequency (VHF) band, the ultra-high frequency (UHF) band, and others. As a particular example, f_{H} may be about 13 MHz (e.g. 13.56 MHz).

Although there is no requirement that the RF frequency of the SP pulse f_{S} be any particular frequency, it may be higher than both f_{H} and f_{L} in certain embodiments. For example, f_{S} may be in the HF band, the VHF band, the UHF band, and above. As a particular example, the RF frequency of the SP pulse f_{S} may be about 26 MHz. As another particular example, the RF frequency of the SP pulse f_{S} may be about 13 MHz (e.g. 13.56 MHz).

Periodic plasma process wo does not rely on any specific power level values for the SP pulse, the LBP pulse, or the HBP pulse, as particular values may depend on the particular plasma chemistry being applied, the plasma tool being used, the semiconductor structure being processed, the desired effect of periodic plasma process 100, and/or other factors. However, in one example, the relative power levels of the various pulses may be as shown. Additionally, although certain types of pulses are shown as having a zero power level during certain phases 106, other embodiments may differ. As just one example, power ranges for the SP pulse, the LBP pulse, or the HBP pulse may be 100-1000 W, 0-50 W, and 0-50 W, respectively; however, different power ranges may be appropriate for particular implementations.

In the illustrated example, pulse cycle 104 has a duration t_{cycle}, which may be any suitable time, according to particular implementations. As shown, phase 106a has duration t₁, phase 106b has duration t₂, and phase 106c has duration t₃. In the illustrated example for cycle 104 in FIG. 1, phases 106a, 106b, and 106c have about equal durations (e.g., t₁=t₂=t₃). In certain embodiments, a pulse frequency for a cycle (e.g., phases 106a, 106b, and 106c) may range from 10 Hz to 0.1 Hz or more such that t_{cycle} may vary from milliseconds to seconds. In another example, a pulse frequency for a cycle (e.g., phases 106a, 106b, and 106c) may range from 10 Hz to 1.0 kHz. These values are provided as examples only; the pulse frequencies for a cycle and t_{cycle} (and associated values of t₁=t₂=t₃) may have any suitable values.

Each phase 106 also has a respective duty cycle within pulse cycle 104. The duty cycle of a particular phase 106 is a percentage of duration t_{cycle} (the duration of pulse cycle 104) occupied by that particular phase 106. For example, phase 106a has a duty cycle of (100*(t₁/t_{cycle}), phase 106b has a duty cycle of (100*(t₂/t_{cycle}), and phase 106c has a duty cycle of (100*(t₃/t_{cycle}). In the example illustrated in FIG. 1, because phases 106a, 106b, and 106c have about equal durations (e.g., t₁=t₂=t₃), the duty cycle of each of phases 106a, 106b, and 106c is about 33.333% (i.e., ⅓). As one particular example, phase 106a may have a duty cycle of 10%-50%, phase 106b may have a duty cycle of 10%-30%, and phase 106c may have a duty cycle of 10%-30%. However, this disclosure is not limited to particular duty cycles for phases 106. It should be understood that the appropriate duty cycles for each phase 106 may vary from implementation-to-implementation, and from cycle to cycle, as adjusting the duty cycles of phases 106 from cycle-to-cycle is a process parameter that may be adjusted to achieve a desired result of the overall periodic plasma process 100.

Although all pulses (SP pulses, HBP pulses, and LBP pulses) are shown to have durations that span an entire phase duration (or longer), this disclosure contemplates pulses having a duration that is less than a phase duration, if appropriate.

As indicated at reference 108, pulse cycle 104 may be repeated as part of periodic plasma process 100, with appropriate adjustments from cycle to cycle, as explained in greater detail with reference to FIG. 2.

Continuing with the lower portion of FIG. 1, a substrate 102 may be the subject of periodic plasma process 100, and an example effect of each phase 106 of pulse cycle 104 is shown with reference to a corresponding version of substrate 102.

In the illustrated example, substrate 102, shown in a cross-sectional view, is a nanowire/nanosheet structure that includes a film stack 110 formed over a base portion 112. Film stack 110 is labeled only in the left-most illustration of substrate 102 to avoid overcrowding the figure, but has a similar structure in the other instances of substrate 102 in FIG. 1. Film stack 110 includes first layers 114 of a first material and second layers 116 of a second material arranged in alternating layers. In one example, either the first layers or the second layers are silicon layers, and the other of the first layers and the second layers are germanium-containing layers (e.g., SiGe layers), such that the film stack is an alternating silicon/SiGe (or other germanium-containing layer) stack. In the illustrated example, second layers 116 are recessed relative to edges of the adjacent first layers 114 such that indents are formed in the film stack. A particular indent is labeled as indent 118. Whether the Si layers or the germanium-containing layers are indented may depend on the type of device being fabricated and subsequent processing planned for substrate 102.

Base portion 112 may be any suitable material and includes silicon, Ge, or SiGe alloy in one example. The content of base portion 112 may depend on the type of device being fabricated and the order and content of the layers 114 and 116 of film stack 110. In a particular example, film stack 110 is formed by growing alternating heteroepitaxial layers of silicon and Ge or SiGe (layers 114 and 116) atop base portion 112.

Substrate 102 includes a vertical recess 120 formed in film stack 110, and an inner spacer structure 122 is located in vertical recess 120. Inner spacer structure 122 may include silicon nitride (SiN), silicon oxynitride (SiON), silicon oxycarbonitride (SiₓO_{y}C_{z}N), or any other suitable material. Inner spacer structure 122 is located on sidewalls of film stack 110 in vertical recess 120 and along a surface at the bottom of the vertical recess 120. In this example, inner spacer structure 122 fills indents 118 formed in film stack 110. For purposes of this example, it will be assumed that a goal of periodic plasma process 100 (of which pulse cycle 104 is a part) is to remove at least some of inner spacer structure 122 along the sidewalls of film stack 110 in vertical recess 120 to form relatively uniform vertical sidewalls while minimizing etching of inner spacer structure 122 at a bottom surface of vertical recess 120.

Although throughout this description and associated figures, substrate 102 (as well as substrate 202 to be described in FIG. 2) is described and shown as having particular layers of particular materials, substrate 102 may have different combinations of the same and/or other materials and/or layers. Furthermore, although substrate 102 is described and shown as having a particular number of layers, substrate 102 may have any suitable number of layers. As just one example, substrate 102 may include one or more masking layers over top surfaces of the film stack. Those masking layers may have been used to form vertical recess 120 in film stack no. In the illustrated example, substrate 102 includes masking layer 123, which may be any material suitable for masking. For example, masking layer 123 may include an organic layer (e.g., an ACL), a hard mask layer, and/or any other suitable materials.

Returning to periodic plasma process 100, to etch inner spacer structure 122 in the desired manner, substrate 102 may be positioned in a processing chamber of a plasma tool (e.g., on a substrate holder/platform), and a gas combination may be supplied to the processing chamber (or a remote chamber for a remotely-generated plasma). A number of plasma process parameters would be set to generate the desired plasma. Those plasma process parameters may include temperature, pressure, gas flow rates, RF SP, RF BP, and duration.

In certain embodiments, a same gas compound is introduced into a plasma process chamber throughout periodic plasma process 100 and/or pulse cycle 104. Although this disclosure contemplates using any suitable gases and gas combinations as may be appropriate for a given implementation, in certain embodiments, the gas combination includes an etchant gas and a carrier gas. As an example, the etchant gas may include a fluorocarbon (CFₓ, such as C₄F₆ or C₄F₈) or hydrofluorocarbon (CHF₃ or CH₃F), which may be written generically as CₓF_{y}H_{z}. As an example, the carrier gas may include at least one of helium (He), nitrogen (N₂), hydrogen (H₂), or argon (Ar).

Phase 106a, which may be referred to as an elevated etch phase, may include generating relatively large amounts of etch species 124 for lateral etching of inner spacer structure 122. In an example, etch species 124 of a generated plasma includes atomic fluorine dissociated from the etchant gas. As described above, during phase 106a an SP pulse is applied at a relatively high power level Pₛ₁, which facilitates the dissociation, creating elevated amounts of etch species 124 (e.g., atomic fluorine or another suitable etchant) for lateral etching of inner spacer structure 122. In certain embodiments, phase 106a includes applying, concurrently with applying the SP pulse at the relatively high power level Pₛ₁, an HBP pulse at a relatively low power level P_{H1}. The inclusion of a relatively low power level HBP pulse may be used to minimize or otherwise reduce etching of inner space structure 122 at the bottom of vertical recess 120 by directing etch species 124 to the sidewalls of film stack 110 in vertical recess 120 to etch inner spacer structure 122 along those sidewalls and thereby minimize or otherwise reduce etching of inner spacer structure 122 at the bottom of vertical recess 120. In other words, the inclusion of an HBP pulse may in phase 106a may promote lateral etching of inner spacer structure 122.

In certain embodiments, phase 106a is implemented without applying an HBP pulse but while still applying the SP pulse, potentially at a high power level. In such an embodiment, etch species 124 may be freer to roam within the process chamber in multiple directions, which may result in a more aggressive isotropic etch of inner space structure 122.

Phase 106b, which may be referred to as an etch-and-deposition phase (or a deposition thickness control phase), may provide concurrent etching and deposition to protect the sidewall and bottom inner spacer structure 122. During phase 106b, both the etch species 124 and an ion species 126 (e.g., carbon monofluoride (CFₓ), or simply CF+ for the ion) are generated and flow into vertical recess 120. Phase 106b may include applying the SP pulse at a continued high power level Pₛ₁ and also applying an LBP pulse at a moderate power level P_{L2}. The power level Pₛ₂ of the SP pulse in phase 106b might or might not be the same as the power level Pₛ₁ of the SP pulse applied in phase 106a. Etch species 124 continue to etch inner spacer structure 122, particularly along sidewalls of the film stack, while ion species 126 (e.g., low energy ions in phase 106b) passivate on exposed surfaces of inner spacer structure 122 to inhibit etching of those surfaces. Ion species 126 and the application of the LBP pulse at the moderate power level P_{L2} may facilitate deposition of passivation layer 128 on inner spacer structure 122. On balance, the etching of inner spacer structure 122 occurs at a slower rate in phase 106b relative to phase 106a.

In phase 106c, which may be referred to as an elevated deposition phase, deposition may be performed by passivating species (ion species 126 (e.g., carbon monofluoride (CFₓ), or simply CF+ for the ion)) on exposed surfaces of inner spacer structure 122 to continue to form passivation layer 128. In certain embodiments, the SP pulse (at a relatively lower power level Pₛ₃) and HBP pulse (at a higher power level P_{H3} relative to a power level P_{H1} of the HBP pulse at phase 106a) applied at phase 106c cause high energy versions of ion species 126, such as CF+, to be generated. Phase 106c may include applying the SP pulse to the processing chamber at a reduced power level Psi relative to a power level Pₛ₁/Pₛ₂ of the SP pulse applied in phases 106a and 106b, and applying an HBP pulse to the processing chamber at an associated power level P_{H3}. In certain embodiments, power level P_{H3} is greater than power level P_{H1} (to the extent an HBP pulse was applied to the processing chamber in phase 106a). In certain embodiments, the combination of a reduced power level Psi of the SP pulse and the application of an HBP pulse encourages the passivating species (e.g., ion species 126) to attach to exposed surfaces of inner spacer structure 122, and particularly at the bottom of vertical recess 120.

Although ion species 126 are not shown in the version of substrate 102 that corresponds to phase 106a, ion species 126 also may be generated and present in the processing chamber; however, due to the selected BP and the high power level for the SP pulse, introduction of such ion species 126 in vertical recess 120 likely would be minimal.

As shown by the bidirectional line 130 at the top of FIG. 1, phase 106a is more etch-species heavy, meaning phase 106a more aggressively etches substrate 102 (inner spacer structure 122) while phase 106c is more ion-heavy, meaning phase 106c more aggressively passivates exposed surfaces of substrate 102 (inner spacer structure 122) to thereby inhibit etching of the exposed surfaces, and particularly at the bottom surface of vertical recess 120. Given that the duty cycles of phases 106a and 106c are about equal and that phase 106b is an etch-and-deposition phase, the particular pulse cycle 104 shown in FIG. 1 is fairly balanced between etching and deposition.

In addition to the gas combination, RF SP (and associated power level), RF BPA (and associated power level and frequency) and other processing parameters associated with implementing periodic plasma process 100 and its associated phases 106 (e.g., including associated duty cycles), a number of other plasma process parameters may be optimized to achieve the desired profile of inner spacer structure 122/substrate 102. Those plasma process parameters may include temperature, pressure, gas flow rates, and duration. In a particular example process, the gases may include CHF₃ at a flow rate of 20 sccm to 100 sccm, Ar at a flow rate of 200 sccm to 200 sccm, and O₂ at a flow rate of 20 sccm to 50 sccm; and the pressure in the plasma process chamber may be 20 mTorr to 50 mTorr. It should be understood that these gases and associated values are provided as examples only.

FIG. 2 illustrates a schematic timing diagram and corresponding substrate undergoing processing of another example plasma processing method, according to certain embodiments. In part, FIG. 2 illustrates a periodic plasma process that includes multiple multiphase pulse cycles, and a technique of adjusting duty cycles of phases of the pulse cycles across different instances of the pulse cycles, along with associated cross-sectional views of substrate 102 undergoing processing, to achieve greater control over the plasma etch process for etching the substrate, according to certain embodiments.

For brevity and clarity, this description adopts a convention in which elements adhering to the pattern [x02] may be related implementations of a substrate in certain embodiments. For example, except as otherwise stated or readily apparent, substrate 202 may be similar to substrate 102 and periodic plasma process 200 may be similar to periodic plasma process 100. An analogous convention has also been adopted for other elements as made clear by the use of similar terms in conjunction with the described three-digit numbering system.

In particular, FIG. 2 illustrates a periodic plasma process 200 for processing substrate 202. Periodic plasma process 200 has a duration tₜₒₜₐₗ and includes three pulse cycles 204(1), 204(2), and 204(3) (referred to generally as pulse cycles 204), each having respective durations t_{cycle1}, t_{cycle2}, and t_{cycle3}. The duration tₜₒₜₐₗ of periodic plasma process 200 is the sum of the durations t_{cycle1}, t_{cycle2}, and t_{cycle3} of pulse cycles 204(1), 204(2), and 204(3), respectively, although one or more delays may be introduced between pulse cycles 204 if appropriate. Additionally, some or all of durations t_{cycle1}, t_{cycle2}, and t_{cycle3} of pulse cycles 204(1), 204(2), and 204(3), respectively, might be the same or might be different.

Each pulse cycle 204 includes three phases 206a, 206b, and 206c. For example, pulse cycle 204(1) includes phases 206a(1), 206b(1), and 206c(1) each having respective durations tₐ₁, t_{b1}, and t_{c1}. As another example, pulse cycle 204(2) includes phases 206a(2), 206b(2), and 206c(2) each having respective durations tₐ₂, t_{b2}, and t_{c2}. As another example, pulse cycle 204(3) includes phases 206a(3), 206b(3), and 206c(3) each having respective durations tₐ₃, t_{b3}, and t_{c3}. The duration t_{cycle} of a pulse cycle 204 is the sum of durations tₐ, t_{b}, and t_{c} of phases 206a, 206b, and 206c, respectively, of that pulse cycle 204, although one or more delays may be introduced between phases 206 if appropriate. Additionally, some or all of durations tₐ, t_{b}, and t_{c} of phases 206a, 206b, and 260c, respectively, might be the same or might be different.

From execution-to-execution of pulse cycles 204, one or more plasma process parameters may be adjusted to achieve enhanced control of the etch process, including both etch and deposition phases of the etch process. For example, for different instances of a pulse cycle 204, one or more plasma process parameters may be adjusted, including potentially duty cycles of corresponding phases 206 across different pulse cycles 204; durations of corresponding phases 206 across different pulse cycles 204; bias pulse durations (whether an LBP pulse or an HBP pulse) relative to another instance of that pulse in a corresponding phase 206 of another pulse cycle 204; SP pulse durations; power levels of one or more of SP, LBP, and/or HBP pulses relative to another instance of that pulse in a corresponding phase 206 of another pulse cycle 204; a number of phases 206 (e.g., one or more phases 206 could be omitted in another pulse cycle 204); and/or an execution order of the phases 206 in another pulse cycle 204. The ability to adjust these parameters provides a highly tunable plasma etch process that can gradually etch desired portions of a substrate (e.g., inner spacer structure on sidewall portion of a recess in a nanowire/nanosheet structure), while still inhibiting etching of other portions of the substrate (e.g., inner spacer structure at a bottom surface of the recess). Furthermore, this tunability may be accomplished with a single etch process without invoking distinct processes of varying types that provide a harsh environment for etching substrate 102.

As to periodic plasma process 200, phases 206a, 206b, and 206c of a given pulse cycle 204 generally correspond to phases 106a, 106b, and 106c of pulse cycle 104 of periodic plasma process 100 of FIG. 1. However, in periodic plasma process 200 of FIG. 2, which includes multiple pulse cycles 204, the duty cycles and durations of phases 106a, 106b, and 106c are adjusted from pulse cycle 204-to-pulse cycle 204 to control etching of substrate 202.

As described above, each phase 206 has a respective duty cycle within a corresponding pulse cycle 204. The duty cycle of a particular phase 206 is a percentage of duration t_{cycle} (the duration of a pulse cycle 204) occupied by that particular phase 206. For example, phase 106a(1) has a duty cycle of (100*(tₐ₁/t_{cycle1}), phase 106b(1) has a duty cycle of (100*(t_{b1}/t_{cycle1}), and phase 106c(1) has a duty cycle of (100*(t_{c1}/t_{cycle1}). As another example, phase 106a(2) has a duty cycle of (100*(tₐ₂/t_{cycle2}), phase 106b(2) has a duty cycle of (100*(t_{b2}/t_{cycle2}), and phase 106c(2) has a duty cycle of (100*(t_{c2}/t_{cycle2}). As another example, phase 106a(3) has a duty cycle of (100*(tₐ₃/t_{cycle3}), phase 106b(3) has a duty cycle of (100*(t_{b3}/t_{cycle3}), and phase 106c(3) has a duty cycle of (100*(t_{c3}/t_{cycle3}).

Phase 206a (similar to phase 106a) generally provides an elevated etch phase that etches a target material. Phase 206b (similar to phase 106b) generally provides an etch-and-deposition phase that provides balanced amounts of etch and deposition. Phase 206c (similar to phase 106c) generally provides an elevated deposition phase that promotes formation of a passivation layer. Adjusting duty cycles of these phases from one pulse cycle 204 to another pulse cycle 204 can provide a greater degree of control over whether a particular pulse cycle 204 predominately etches (e.g., a target material), predominately deposits (e.g., a passivation layer), or provides a balance between etching and deposition.

In pulse cycle 204(1), phase 206a(1) has a relatively larger duty cycle than either phase 206b(1) or phase 206c(1), and a duty cycle of a combination of phase 206a(1) and phase 206b(1) is greater than fifty percent of pulse cycle 204(1). This means pulse cycle 204(1) is a predominately etching pulse cycle. In pulse cycle 204(2), phase 206a(2), phase 206b(2), and phase 206c(2) have about equal duty cycles (and durations), such that the duty cycle of each of phases 206a(2), 206b(2), and 206c(2) is about 33.333% (i.e., ⅓). This means pulse cycle 204(2) is generally balanced between etching and deposition, and is generally similar to pulse cycle 104 of FIG. 1. In pulse cycle 204(3), phase 206a(3) has a relatively smaller duty cycle than either phase 206b(3) or phase 206c(3) and a duty cycle of a combination of phase 206b(1) and phase 206c(1) is greater than fifty percent of pulse cycle 204(3). This means pulse cycle 204(3) is a predominately deposition pulse cycle.

Although adjusting duty cycles of phases 106 from pulse cycle 104-to-pulse cycle 104 to achieve greater control is primarily described, this disclosure contemplates adjusting one or more other plasma process parameters, in addition to or instead of adjusting duty cycles, to achieve greater control of the etch process.

Turning to substrate 202, substrate 202 may be the target of periodic plasma process 200 of FIG. 2, and an example effect of each pulse cycle 204 is shown with reference to a corresponding version of substrate 202. Substrate 202, shown in a cross-sectional view, is generally similar to substrate 102 of FIG. 1, and includes film stack 210 of alternating first layers 214 of a first material and second layers 216 of a second material, base portion 212, indents 218, vertical recess 220 formed in film stack 210, an inner spacer structure 222 located in vertical recess 220 (along sidewalls of film stack 210 in vertical recess 220 into indents 218 and along a surface at the bottom of vertical recess 220), and a masking layer 223. Additional details regarding substrate 202 are incorporated by reference from the description of substrate 102 without being repeated.

For purposes of this example, it will be assumed that a goal of periodic plasma process 200 is to remove at least some of inner spacer structure 222 along the sidewalls of film stack 210 in vertical recess 220 to form relatively uniform vertical sidewalls while minimizing etching of inner spacer structure 222 at a bottom surface of vertical recess 220.

To etch inner spacer structure 222 in the desired manner, substrate 202 may be positioned in a processing chamber of a plasma tool (e.g., on a substrate holder/platform), and a gas combination may be supplied to the processing chamber (or a remote chamber for a remotely-generated plasma). A number of plasma process parameters would be set to generate the desired plasma. Those plasma process parameters may include temperature, pressure, gas flow rates, RF SP, RF BP, and duration.

In certain embodiments, a same gas compound is introduced into a plasma process chamber throughout periodic plasma process 200 and/or pulse cycles 204. Although this disclosure contemplates using any suitable gases and gas combinations as may be appropriate for a given implementation, in certain embodiments, the gas combination includes an etchant gas and a carrier gas. As an example, the etchant gas may include a fluorocarbon (CFₓ, such as C₄F₆ or C₄F₈) or hydrofluorocarbon (CHF₃ or CH₃F), which may be written generically as CₓF_{y}H_{z}. As an example, the carrier gas may include at least one of He, N₂, H₂, or Ar.

As described above, embodiments of this disclosure provide a time-modulated plasma process for trimming inner spacer structure 222 using multi-frequency, multiphase pulsing schemes. A deposition phase and an etch phase can be tuned separately by varying power, duty cycle, bias duration, and/or other suitable plasma process parameters. Multiple pulsing schemes with various operating parameters may be used for different periods of time to control an amount of lateral and vertical etching.

In the illustrated example, as described above, due at least in part to the relatively large duty cycle of phase 206a(1) (an elevated etching phase) in pulse cycle 204(1), pulse cycle 204(1) promotes aggressive etching of inner spacer structure 222. To avoid over-etching inner spacer structure 222, particularly at the bottom of vertical recess 220, pulse cycle 204(2) slows the etch process by balancing (in this example, using equal duty cycles) elevated etch phase 206a(2), etch-and-deposition phase 206b(2), and elevated deposition phase 206c(2), which still allows etching but also forms passivation layer 228 along sidewalls of film stack 210 in vertical recess 220 and at the bottom of vertical recess 220. Due at least in part to the relatively large duty cycle of phase 206c(3) (an elevated deposition phase) in pulse cycle 204(3), pulse cycle 204(3) promotes aggressive deposition of passivation layer 228, particularly at the bottom of vertical recess 220, while still allowing some lateral etching of inner spacer structure 222 along sidewalls of film stack 210 in vertical recess 220.

In certain embodiments, the phases 206 of a pulse cycle 204 may be performed continuously or stepwise, and each pulse cycle 204 of the periodic plasma process 200 may be performed continuously or stepwise with respect to a prior or subsequent pulse cycle 204 of periodic plasma process 200. In certain embodiments, a continuous cyclic process (or portions of a process) may include repeatedly and consecutively performing a pulse cycle having substantially similar process parameters as repeatedly performed (e.g., repeatedly and consecutively performing pulse cycle 204(1), repeatedly and consecutively performing pulse cycle 204(2), or repeatedly and consecutively performing pulse cycle 204(3)). In certain embodiments, a stepwise cyclic process (or portions of a process) may include consecutively performing pulse cycles having different process parameters as consecutively performed (e.g., switching from pulse cycle 204(1) to pulse cycle 204(2) or 204(3), switching from pulse cycle 204(2) to pulse cycle 204(1) or 204(3), or switching from pulse cycle 204(3) to pulse cycle 204(1) or 204(2)). Of course, other implementations for continuous and stepwise processes (or portions of processes) are possible as will be understood by those of skill in the art.

In certain embodiments, execution of multiple and potentially all pulse cycles 204 of periodic plasma process 200 occurs with substrate 202 being positioned and remaining in a single processing chamber of a plasma processing tool.

Although periodic plasma process 200 is shown and described to have three pulse cycles 204 (pulse cycles 204(1), 204(2), and 204(3)), this disclosure contemplates periodic plasma process 200 including any suitable number of pulse cycles 204. The appropriate number of pulse cycles 204, along with all other potential adjustments that might be made from pulse cycle 204-to-pulse cycle 204 for a given implementation, depends on various factors, including the materials of substrate 202, the gas chemistry, the desired critical dimension of vertical recess 220, the acceptable amount of time that the etch process may introduce to the entire process of fabricating a device, and/or other suitable factors.

Furthermore, due at least in part to the ability of a periodic plasma process 200 to be tuned, embodiments of this disclosure may achieve a desired result whether the target substrate 202 being etched includes a vertical recess 220 having a relatively small critical dimension or includes a vertical recess 220 having a large critical dimension. The multiphase multifrequency plasma etch process with adjustable duty cycles (and/or other plasma process parameters) can be tailored to structures that benefit from different etch schemes. For example, a smaller critical dimension may suggest a larger aspect ratio, which may benefit from additional execution time, including potentially more executions of pulse cycles 204.

A particular wafer (e.g., substrate 102/202) may include some features that have a relatively low aspect ratio and other features that have a relatively high aspect ratio. As just one non-limiting example of a technique for etching both simultaneously, and assuming a total etching time of about two minutes, the duty cycle of an elevated etching phase (e.g., phase 106a/phase 206a) may initially be about 40% and may be ramped down linearly or nonlinearly over the total etching time. Continuing with this example, over the course of ramping down the duty cycle of the elevated etching phase, a periodic plasma process (e.g., process 100/200) may transition from a process in which etching exceeds deposition to a process in which deposition exceeds etching (e.g., as shown in FIG. 2). In a nonlinear ramping example, the elevated etching phase could have a duty cycle in a first pulse cycle of 40% for a time of 5o seconds, a duty cycle in a subsequent second pulse cycle of 30% for a time of 100 seconds (e.g., a longer time, but a lower duty cycle), and a duty cycle in a subsequent third pulse cycle of 20% for a time of 5o seconds. Of course, these values are provided as examples only.

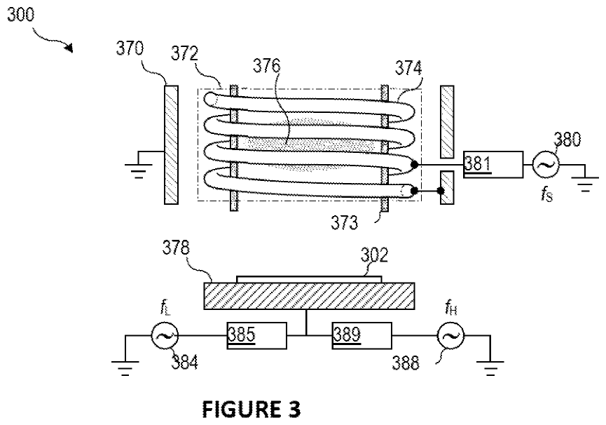

FIG. 3 illustrates a schematic diagram of an example plasma processing apparatus 300, according to certain embodiments. Plasma processing apparatus 300 may be used to perform the plasma processing methods described herein, such as the plasma processing method of FIGS. 1-2 and 4-6, for example.

Plasma processing apparatus 300 includes a grounded outer structure 370 surrounding an SP coupling electrode 372 (which may be implemented as a helical resonator antenna 374 which in turn surrounds a dielectric inner surface 373). The helical resonator antenna 374 may be grounded at one end and left free at the other. An RF SP supply 380 is coupled to an SP generator circuit 381 which is in turn coupled to the helical resonator antenna 374 at an appropriate distance from the grounded connection.

The SP coupling location (which may also be referred to as a tap position) may depend on operating frequency as well as other considerations. A plasma 376 (which may be a high-density plasma such as a helical resonator plasma as shown) is generated which is inductively coupled to the SP coupling electrode 372. For example, the dielectric inner surface 373 may be provided between the plasma 376 and the helical resonator antenna 374 to facilitate inductive coupling. An RF LBP supply 384 may be coupled to an LBP generator circuit 385 which is coupled to a substrate holder 378 (e.g. a lower plate electrode (LEL)). The substrate holder 378 may serve as an electrostatic chuck (ESC) to support and retain a substrate 302. Substrate 302 may be any of the substrates undergoing plasma processing according to embodiments described herein.

The helical resonator antenna 374 may be a full-wave, half-wave, or quarter-wave antenna. For example, if the helical resonator antenna 374 is driven at using RF power with a frequency of about 26 MHz, a quarter-wave helical resonator antenna may be about 2.25 m in length. Similarly, if the helical resonator antenna 374 is driven at using RF power with a frequency of 13.56 MHz, a quarter-wave helical resonator antenna may be about 5.5 m in length. As the RF frequency increases, the length of the helical resonator antenna 374 may decrease. For example, a quarter-wave helical resonator antenna driven at about 50 MHz may be about 1.5 m in length.

Although this disclosure illustrates and describes example plasma processing apparatus 300, embodiments of this disclosure can be implemented using any suitable type of semiconductor processing tool(s). Certain embodiments may be performed in a high-density plasma reactor. The particular plasma tool may include an inductively-coupled plasma (ICP) tool, a capacitively-coupled coupled plasma (CCP) (also referred to as a transformer-coupled plasma (TCP)) tool, microwave plasma tool, a helicon wave sources (HWS) tool, high frequency VHF tool, a spiral resonator tool, or any other suitable type of plasma generator. In certain embodiments, a plasma tool that is capable of generating reliable pulses, and that can variably pulse may facilitate implementing a multiphase, multi-frequency plasma process.

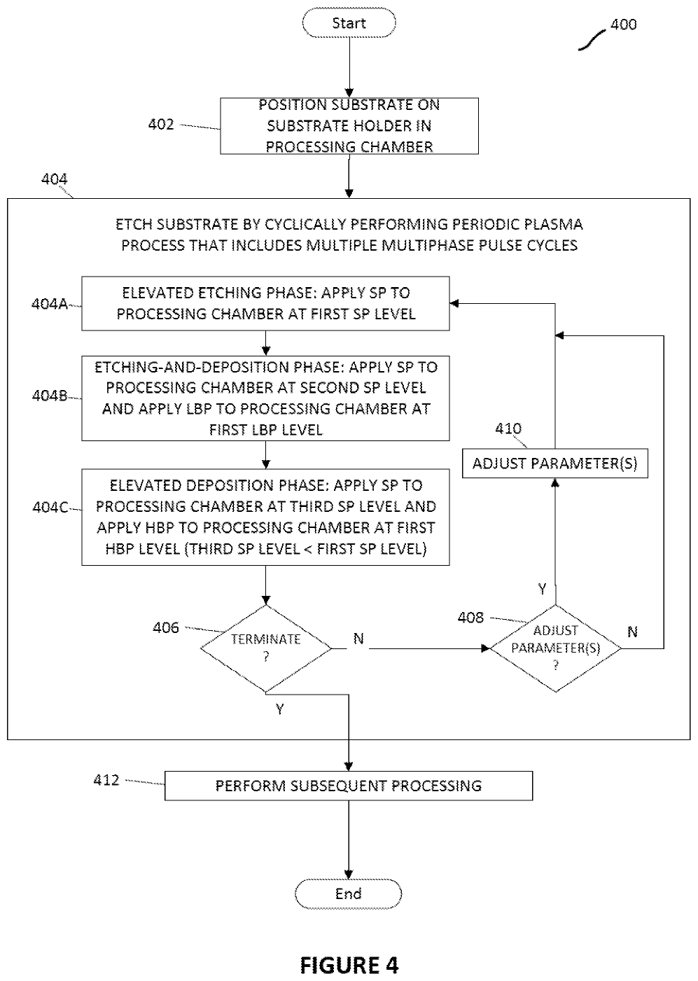

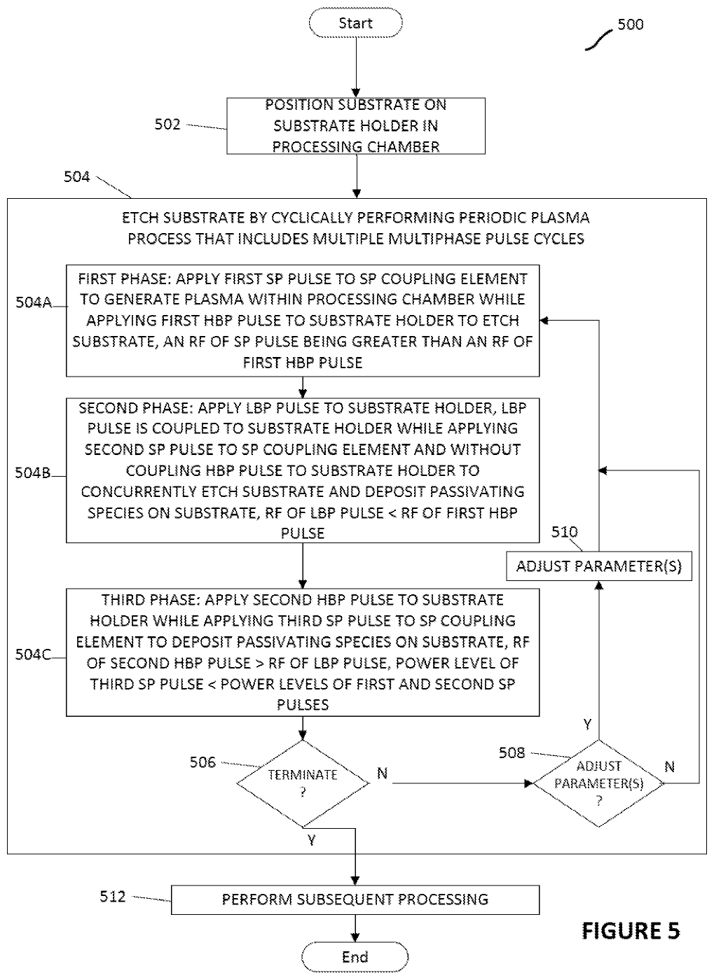

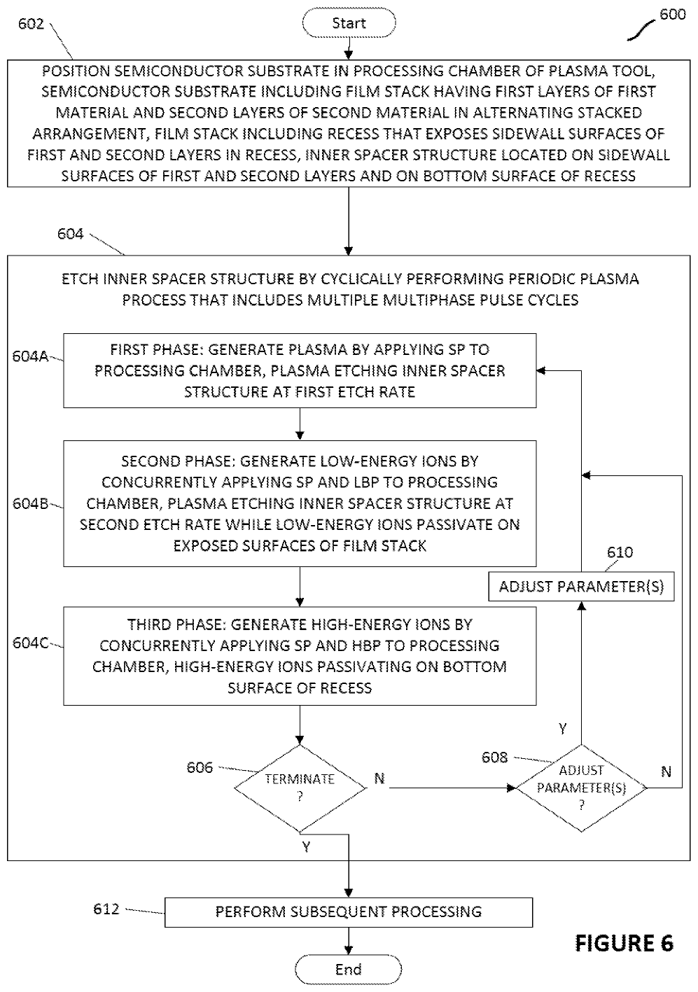

FIG. 4 illustrates an example method 400 of plasma processing, according to certain embodiments. Method 400 may be combined with other methods and performed using the systems and apparatuses described herein. For example, method 400 may be combined with any of the embodiments of FIGS. 1-3. Additionally, method 400 may be combined with other methods, such as any of the methods of FIGS. 5-6, for example. Although shown in a logical order, the arrangement and numbering of the steps of method 400 are not intended to be limited. The steps of method 400 may be performed in any suitable order or concurrently with one another as may be apparent to a person of skill in the art.

At step 402, a substrate (e.g., substrate 102 or 202) may be positioned on a substrate holder in a processing chamber of a plasma processing tool.

At step 404, the substrate may be etched by cyclically performing a periodic plasma process that includes multiple multiphase pulse cycles. In the illustrated example, each multiphase pulse cycle includes three phases, shown as step 404A, 404B, and 404C.

Step 404A may be an elevated etching phase that includes applying an SP to the processing chamber at a first SP level. In certain embodiments, the elevated etching phase may include, concurrently with applying the SP to the processing chamber at the first SP level, applying the HBP to the processing chamber at a second HBP level. The second HBP level may be less than the first HBP level.

Step 404B may be an etching-and-deposition phase that includes applying the SP to the processing chamber at a second SP level and applying an LBP to the processing chamber at a first LBP level. In certain embodiments, the first SP level and the second SP level are substantially equal.

Step 404C may be an elevated deposition phase that includes applying the SP to the processing chamber at a third SP level and applying an HBP to the processing chamber at a first HBP level. The third SP level may be less than the first SP level.

In certain embodiments, during each phase of a multiphase pulse cycle, a same gas combination is supplied to the processing chamber. In certain embodiments, during each multiphase pulse cycle of the multiple multiphase pulse cycles, a same gas combination is supplied to the processing chamber such that the same gas combination is supplied to the processing chamber across etch step 404.

At step 406, a determination is made regarding whether to terminate the etch process of step 404.

If a determination is made at step 406 not to terminate the etch process of step 404, then the method may proceed to step 408 to determine whether to adjust one or more plasma process parameters for the next cycle of the etch process of step 404. The one or more plasma process parameters to adjust may include a duration of the elevated etching phase, the etching-and-deposition phase, or the elevated deposition phase; a power level of the SP, the LBP, or the HBP from the elevated etching phase, the etching-and-deposition phase, or the elevated deposition phase of the previous multiphase pulse cycle to the elevated etching phase, the etching-and-deposition phase, or the elevated deposition phase to the next multiphase pulse cycle; a duty cycle of the elevated etching phase, the etching-and-deposition phase, or the elevated deposition phase; an execution order of the elevated etching phase, the etching-and-deposition phase, and the elevated deposition phase from the previous multiphase pulse cycle to the next multiphase pulse cycle; and/or any other suitable plasma process parameter.

If a determination is made at step 408 to adjust one or more plasma process parameters for the next cycle of the etch process of step 404, then the one or more adjustments may be made at step 410 and the method may return to step 404a to perform an additional cycle of steps 404A-404C according to the adjusted one or more parameters. In certain embodiments, adjusting the parameters may include shuffling the order of steps 404A, 404B, and 404C (reordering the phases), or even omitting one or more steps 404A, 404B, and 404C (omitting one or more phases) for the next cycle.

If a determination is made at step 408 not to adjust one or more plasma process parameters for the next cycle of the etch process of step 404, then the method may return to step 404a to perform an additional cycle of steps 404A-404C according to the previous plasma process parameters.

If a determination is made at step 406 to terminate the etch process of step 404, then the method may proceed to step 412 to perform subsequent processing. This disclosure contemplates the subsequent processing comprising any suitable processing operations as may be appropriate for a given implementation. In certain embodiments, method 400 may be integrated into a process for forming certain layers of the film stack into nanowires/nanosheets for a channel region of a semiconductor device, such as a GAA device, and the subsequent processing steps may include forming (or continuing to form) certain layers of the film stack into those nanowires/nanosheets. In certain embodiments, if a passivation layer remains on the inner spacer layer, the subsequent processing may include performing a suitable etch process (e.g., a wet etch process or a dry etch process) to partially or fully remove the remaining passivation layer, if desired.

Method 400 then may end.

FIG. 5 illustrates an example method 500 of plasma processing, according to certain embodiments. Method 500 may be combined with other methods and performed using the systems and apparatuses described herein. For example, method 500 may be combined with any of the embodiments of FIGS. 1-3. Additionally, method 500 may be combined with other methods, such as any of the methods of FIGS. 4 and 6, for example. Although shown in a logical order, the arrangement and numbering of the steps of method 500 are not intended to be limited. The steps of method 500 may be performed in any suitable order or concurrently with one another as may be apparent to a person of skill in the aft.

At step 502, a substrate (e.g., substrate 102 or 202) may be positioned on a substrate holder in a processing chamber of a plasma processing tool.

At step 504, the substrate may be etched by cyclically performing a periodic plasma process that includes multiple multiphase pulse cycles. In the illustrated example, each multiphase pulse cycle includes three phases, shown as step 504A, 504B, and 504C.

Step 504A may be first phase that includes applying a first SP pulse to an SP coupling element to generate plasma within the processing chamber while applying a first HBP pulse to the substrate holder to etch the substrate. An RF of the first SP pulse may be greater than an RF of the first HBP pulse.

Step 504B may be a second phase that includes applying an LBP pulse to the substrate holder, with the LBP pulse being coupled to the substrate holder while applying a second SP pulse to the SP coupling element and without coupling an HBP pulse to the substrate holder to concurrently etch the substrate and deposit passivating species on the substrate. An RF of the LBP pulse may be less than an RF of the first HBP pulse. In certain embodiments, the power level of the first SP pulse and the power level of the second SP pulse are substantially equal. In certain embodiments, the RF of the LBP pulse is less than 2 MHz, and the RF of the first HBP and the RF of the second HBP are in a range from 3 MHz to 30 MHz.

Step 504C may be a third phase that includes applying a second HBP pulse to the substrate holder while applying a third SP pulse to the SP coupling element to deposit passivating species on the substrate. An RF of the second HBP pulse may be greater than the RF of the LBP pulse, and a power level of the third SP pulse may be less than a power level of the first SP pulse and less than a power level of the second SP pulse.

In certain embodiments, during each phase of a multiphase pulse cycle, a same gas combination is supplied to the processing chamber. In certain embodiments, during each multiphase pulse cycle of the multiple multiphase pulse cycles, a same gas combination is supplied to the processing chamber such that the same gas combination is supplied to the processing chamber across etch step 504.

The first phase has a first duration, the second phase has a second duration, and the third phase has a third duration. In certain embodiments, two or more of the first duration, the second duration, and the third duration are different within a single cycle of the periodic plasma process (etch step 504). In certain embodiments, the first duration, the second duration, and the third duration are a same duration within a single cycle of the periodic plasma process. In certain embodiments, at least two of the first duration, the second duration, and the third duration have different corresponding durations in a first cycle than in a second cycle, while a time length of the first and second cycles remains the same, such that a duty cycle of at least two of the first phase, the second phase, and the third phase changes.

At step 506, a determination is made regarding whether to terminate the etch process of step 504.

If a determination is made at step 506 not to terminate the etch process of step 504, then the method may proceed to step 508 to determine whether to adjust one or more plasma process parameters for the next cycle of the etch process of step 504. Step 508 may be similar to step 408, the details of which are incorporated by reference.

If a determination is made at step 508 to adjust one or more plasma process parameters for the next cycle of the etch process of step 504, then the one or more adjustments may be made at step 510 and the method may return to step 504a to perform an additional cycle of steps 504A-504C according to the adjusted one or more parameters. In certain embodiments, adjusting the parameters may include shuffling the order of steps 504A, 504B, and 504C (reordering the phases), or even omitting one or more steps 504A, 504B, and 504C (omitting one or more phases) for the next cycle.

If a determination is made at step 508 not to adjust one or more plasma process parameters for the next cycle of the etch process of step 504, then the method may return to step soda to perform an additional cycle of steps 504A-504C according to the previous plasma process parameters.

If a determination is made at step 506 to terminate the etch process of step 504, then the method may proceed to step 512 to perform subsequent processing. Step 512 may be similar to step 412, the details of which are incorporated by reference.

Method 500 then may end.

FIG. 6 illustrates an example method 600 of plasma processing, according to certain embodiments. Method 600 may be combined with other methods and performed using the systems and apparatuses described herein. For example, the method 600 may be combined with any of the embodiments of FIGS. 1-3. Additionally, method boo may be combined with other methods, such as any of the methods of FIGS. 4-5, for example. Although shown in a logical order, the arrangement and numbering of the steps of method 600 are not intended to be limited. The steps of method 600 may be performed in any suitable order or concurrently with one another as may be apparent to a person of skill in the art.

At step 602, a substrate (e.g., substrate 102 or 202) may be positioned on a substrate holder in a processing chamber of a plasma processing tool. In certain embodiments, the substrate includes a film stack having first layers of a first material and second layers of a second material in an alternating stacked arrangement. The film stack may include a recess that exposes sidewall surfaces of the first and second layers in the recess, and an inner spacer structure may be located on the sidewall surfaces of the first and second layers and on a bottom surface of the recess. At least a portion of the sidewall surfaces of the second layers may be recessed relative to the sidewall surfaces of adjacent first layers such that indents are formed in the film stack at the first layers. The inner spacer structure may extend into the indents.

In certain embodiments, the first material is silicon and the second material is SiGe. In certain other embodiments, the first material is SiGe and the second material is silicon. In certain embodiments, the inner spacer structure includes SiN, SiON, or SiₓO_{y}C_{z}N.

Prior to being positioned in the processing chamber, the substrate may include the film stack having the first layers and the second layers in the alternating stacked arrangement, including the recess that exposes the sidewall surfaces of the first and second layers in the recess, and the inner spacer structure located on the sidewall surfaces of the first and second layers and on the bottom surface of the recess. Alternatively, one or more of the film stack having the first layers and the second layers in the alternating stacked arrangement, the recess that exposes the sidewall surfaces of the first and second layers in the recess, or the inner spacer structure located on the sidewall surfaces of the first and second layers and on the bottom surface of the recess may be formed on the substrate after positioning the substrate in the processing chamber but prior to etching the inner spacer structure by cyclically performing the periodic plasma process. Furthermore, it will be understood that step 602 contemplates either possibility.

At step 604, the substrate may be etched by cyclically performing a periodic plasma process that includes multiple multiphase pulse cycles, with the inner spacer structure being the target of the etch process. In the illustrated example, each multiphase pulse cycle includes three phases, shown as step 604A, 604B, and 604C.

Step 604A may be first phase that includes generating a plasma by applying an SP to the processing chamber, the plasma etching the inner spacer structure at a first etch rate.

Step 604B may be a second phase that includes generating low-energy ions by concurrently applying the SP and an LBP to the processing chamber, the plasma etching the inner spacer structure at a second etch rate while the low-energy ions passivate on exposed surfaces of the film stack. In certain embodiments, the SP is applied to the processing chamber in the second phase at a same power level as the SP is applied to the processing chamber in the first phase and the second phase. In certain embodiments, the first etch rate of the first phase (step 604A) is greater than the etch rate of the second phase (step 604B).

Step 604C may be a third phase that includes generating high-energy ions by concurrently applying the SP and an HBP to the processing chamber, the high-energy ions passivating on the bottom surface of the recess. In certain embodiments, the SP is applied to the processing chamber in the third phase at a lower power level than the SP is applied to the processing chamber in the first phase and the second phase.

In certain embodiments, during each phase of a multiphase pulse cycle, a same gas combination is supplied to the processing chamber. In certain embodiments, during each multiphase pulse cycle of the multiple multiphase pulse cycles, a same gas combination is supplied to the processing chamber such that the same gas combination is supplied to the processing chamber across etch step 604. As just one example, the gas combination may include an etchant gas (e.g., fluorocarbon or hydrofluorocarbon) and a carrier gas. An etch species may include fluorine dissociated from the etchant gas. The low-energy ions and high-energy ions may include CF+.

The first phase has a first duration, the second phase has a second duration, and the third phase has a third duration. In certain embodiments, two or more of the first duration, the second duration, and the third duration are different within a single cycle of the periodic plasma process (etch step 604). In certain embodiments, the first duration, the second duration, and the third duration are a same duration within a single cycle of the periodic plasma process. In certain embodiments, at least two of the first duration, the second duration, and the third duration have different corresponding durations in a first cycle than in a second cycle, while a time length of the first and second cycles remains the same, such that a duty cycle of at least two of the first phase, the second phase, and the third phase changes.

At step 606, a determination is made regarding whether to terminate the etch process of step 604. The periodic plasma process may be terminated for any suitable reason. For example, the periodic plasma process may be terminated in response to the inner space structure on the sidewall surfaces of the first layers and the second layers reaches being desired thickness. As another example, the periodic plasma process may be terminated in response to a predetermined number of cycles being executed. As another example, the periodic plasma process may be terminated in response to the inner spacer structure being fully removed from the sidewall surfaces of the first layers and the second layers.

If a determination is made at step 606 not to terminate the etch process of step 604, then the method may proceed to step 608 to determine whether to adjust one or more plasma process parameters for the next cycle of the etch process of step 604. Step 608 may be similar to step 408, the details of which are incorporated by reference.

If a determination is made at step 608 to adjust one or more plasma process parameters for the next cycle of the etch process of step 604, then the one or more adjustments may be made at step 610 and the method may return to step 604a to perform an additional cycle of steps 604A-604C according to the adjusted one or more parameters. In certain embodiments, adjusting the parameters may include shuffling the order of steps 604A, 604B, and 604C (reordering the phases), or even omitting one or more steps 604A, 604B, and 604C (omitting one or more phases) for the next cycle.

If a determination is made at step 608 not to adjust one or more plasma process parameters for the next cycle of the etch process of step 604, then the method may return to step 604a to perform an additional cycle of steps 604A-604C according to the previous plasma process parameters.

If a determination is made at step 606 to terminate the etch process of step 604, then the method may proceed to step 612 to perform subsequent processing. Step 612 may be similar to step 412, the details of which are incorporated by reference.

Following termination of the etch process of step 604, some or none of the inner spacer structure may remain. In certain embodiments, at least a portion of the inner spacer structure remains on the bottom surface of the recess. In certain embodiments, at least a portion of the inner space structure remains on the in the indents on the sidewalls of the film stack, potentially even extending beyond the indents into the recess and possibly on the sidewalls of the film stack. In certain embodiments, the inner space structure is fully removed from the sidewalls and indents of the film stack. In certain embodiments, the inner spacer structure is fully removed from the substrate.

Method 600 then may end.

Although this disclosure primarily illustrates and describes an embodiment that includes three phases, fewer or more phases may be included within a pulse cycle as may be appropriate for a given implementation. Additionally, although this disclosure illustrates and describes particular processing parameters being modified from phase-to-phase and from pulse cycle-to-pulse cycle (e.g., processing parameters, including power, duty cycle, and/or duration), this disclosure contemplates modifying other processing parameters. For example, other processing parameters that may be modified from phase-to-phase and/or from pulse cycle-to-pulse cycle may include pressure, gas flow rate, gas content, temperature, cycle period, number of cycles, and/or any other suitable processing parameter(s) to optimize the etch profile of the structure being etched (e.g., substrate 102).

This disclosure contemplates etch steps 404, 504, and 604 being performed continuously or stepwise. For example, each multiphase pulse cycle, that is the constituent phases of a particular multiphase pulse cycle (e.g., a single pass through etch step 404, 504, or 604), may be performed continuously or stepwise. As another example, each cycle of the periodic plasma process may be performed continuously or stepwise with respect to a prior or subsequent cycle of the periodic plasma process.

With respect to determinations of whether to terminate the etch process (e.g., etch step 404, 504, and 604) and/or adjust one or more plasma process parameters (e.g., steps 408, 508, and 608) for each of methods 400, 500, and 600, the determination may be made according to a predetermined process flow/recipe (referred to for simplicity as predetermined recipe), in situ, or in any other suitable manner. For example, a predetermined recipe may be formulated prior to beginning the periodic plasma etch process (e.g., etch step 404, 504, or 604), based on historical data, test data, operator experience, or the like. As another example, during the periodic plasma process (e.g., etch step 404, 504, or 604), in-situ measurements associated with the periodic plasma process may be determined and the determination of whether to terminate the etch process or adjust one or more plasma process parameters may be determined (and adjusted, if appropriate) in situ according to the in-situ measurements.

More specifically, processing parameters may be changed offline between fabrication instances, in situ during fabrication (e.g., during a pulse cycle or between pulse cycles), or in any other suitable manner. For example, historical data regarding performance of particular processing parameter combinations and the resulting structural measurements (e.g., thickness of resulting layers, damage to the structure, and the like) may be measured, recorded, and analyzed. Using this historical data and associated analysis, a designer may modify one or more processing parameters for future fabrications to attempt to achieve a different result. As another example, during the periodic plasma process, in situ measurement and/or diagnostic tools may be used to gather data associated with the periodic plasma process, and if appropriate, at least one process parameter may be adjusted in situ within a pulse cycle or from one pulse cycle to a future (and potentially next) pulse cycle.

Measurement tools for evaluating the results of the plasma process may include a photodiode in or coupled to a plasma chamber that provides feedback to an RF source system on the ignition and energy of a generated plasma by way of a current from the photodiode that is proportional to the light amplitude of the plasma. In some embodiments, an optical emission spectrometer (OES) is used in place of or in addition to the photodiode to give feedback on plasma ignition. The optical emission spectrometer may also provide spectral data on the plasma to allow for tuning for specific plasma species. Characteristics, such as critical dimensions and pattern defects may be measured using optical techniques such as scatterometry, a scanning electron microscope (SEM), transmission electron microscope (TEM), high-resolution TEM (HR-TEM), scanning probe microscope (SPM), atomic force microscope (AFM), scanning tunneling microscope (STM), or other suitable devices. Although particular measurement tools and techniques are described, any suitable measurement tools and techniques may be used. In certain embodiments, the plasma tool being used may include sensors configured to measure and output in-situ tool data that is output to a data processor. Examples of such sensors may include temperature sensors, pressure sensors, flow meters, spectrometry tools, current/voltage sensors, and the like.

Certain embodiments may provide none, some, or all of the following technical advantages. Relative to conventional techniques that include separate CVD, lateral etching, and vertical etching steps, certain embodiments can achieve deposition, lateral etching, and vertical etching in a processing step in which certain processing parameters are adjusted. This capability may provide better throughput and tunability of ion and passivating species fluxes.

In certain embodiments, a combination of multi-frequency and multiphase pulsing schemes is used to control the balance between etching and deposition. In the context of etching an inner spacer structure of a nanodevice, certain embodiments provide greater control over the etch process to gradually etch desired portions of the inner spacer (e.g., some or all of the portions on the sidewalls of the film stack in a vertical recess of the film stack) in a way that reduces or eliminates defects in adjacent structures and, if desired, preserves desired portions of the inner spacer (e.g., a portion of the inner spacer at the bottom of the recess).

Embodiments of this disclosure may be used to fabricate 3D semiconductor structures, such as GAA FINFET structures; however, GAA FINFET structures are just one example of semiconductor structures that can take advantage of the techniques described herein. The techniques described herein can be used with other structures, including other 3D structures in addition to GAA FINFET structures. As just one example, certain embodiments could be used to perform certain trimming steps in connection with film stacks of silicon oxide, silicon nitride, or a combination of silicon oxide and silicon nitride (e.g., alternating oxide/nitride layers, such as those that might be used in a three-dimensional 3D-NAND stack).

It should be understood that the particular materials, etch processes, and deposition processes described herein are provided as examples only. The particular materials, deposition processes (and associated process conditions), and etch processes (and associated process conditions) may be determined based on process integration goals, etch selectivity, the desired content of the layer stack in the semiconductor structure being formed, and other factors.

One or more deposition processes can be used to form the material layers described herein. For example, one or more depositions can be implemented using spin-coating, CVD, PECVD, PVD, ALD, and/or other deposition processes. The type of deposition process used, the chosen chemicals/gases used for that deposition process, and the process conditions used for that deposition process may be chosen to achieve a desired deposition material and rate for the materials being deposited, or according to other applicable factors.

Similarly, certain etch processes can be implemented using wet etch processes, plasma etch processes, discharge etch processes, and/or other desired etch processes. The type of etch process used, the chosen chemicals/gases used for that etch process, and the process conditions used for that etch process may be chosen to achieve a desired etch rate and selectivity for the material(s) being etched relative to materials not being etched, or according to other applicable factors.

Example embodiments of this disclosure are summarized here. Other embodiments can also be understood from the entirety of the specification as well as the claims filed herein.

Example 1. A method includes positioning a substrate on a substrate holder in a processing chamber and etching the substrate by cyclically performing a periodic plasma process that includes multiple multiphase pulse cycles that each includes an elevated etching phase, an etching-and-deposition phase, and an elevated deposition phase. The elevated deposition phase includes applying an SP to the processing chamber at a first SP level. The etching-and-deposition phase includes applying the SP to the processing chamber at a second SP level and applying an LBP to the processing chamber at a first LBP level. The elevated deposition phase includes applying the SP to the processing chamber at a third SP level and applying an HBP to the processing chamber at a first HBP level, the third SP level being less than the first SP level. A same gas combination may be supplied to the processing chamber during each multiphase pulse cycle of the multiple multiphase pulse cycles.

Example 2. The method of Example 1, where etching the substrate by cyclically performing the periodic plasma process includes adjusting, from a first multiphase pulse cycle of the multiphase pulse cycles to a second multiphase pulse cycle of the multiphase pulse cycles, at least one plasma process parameter, the at least one plasma process parameter being: a duration of the elevated etching phase, the etching-and-deposition phase, or the elevated deposition phase; a power level of the SP, the LBP, or the HBP from the elevated etching phase, the etching-and-deposition phase, or the elevated deposition phase of the first multiphase pulse cycle to the elevated etching phase, the etching-and-deposition phase, or the elevated deposition phase of the second multiphase pulse cycle; a duty cycle of the elevated etching phase, the etching-and-deposition phase, or the elevated deposition phase; or an execution order of the elevated etching phase, the etching-and-deposition phase, and the elevated deposition phase from the first multiphase pulse cycle to the second multiphase pulse cycle.

Example 3. The method of any one of Examples 1-2, where the method further includes determining, during the periodic plasma process, in-situ measurements associated with the periodic plasma process; and adjusting, from the first multiphase pulse cycle to the second multiphase pulse cycle, the at least one plasma process parameter includes adjusting the at least one plasma process parameter in situ according to the in-situ measurements.

Example 4. The method of any one of Examples 1-2, where adjusting, from the first multiphase pulse cycle to the second multiphase pulse cycle, the at least one plasma process parameter includes adjusting the at least one plasma process parameter according to a predetermined recipe, the predetermined recipe being determined prior to performing the periodic plasma process.

Example 5. The method of any one of Examples 1-4, where the elevated etching phase of a first multiphase pulse cycle of the multiphase pulse cycles includes, concurrently with applying the SP to the processing chamber at the first SP level, applying the HBP to the processing chamber at a second HBP level that is less than the first HBP level.

Example 6. The method of any one of Examples 1-5, where the first SP level and the second SP level are substantially equal.

Example 7. The method of any one of Examples 1-6, where each multiphase pulse cycle of the multiple multiphase pulse cycles is performed continuously or stepwise, and each cycle of the periodic plasma process is performed continuously or stepwise with respect to a prior or subsequent cycle of the periodic plasma process.

Example 8. A method includes positioning a substrate on a substrate holder in a processing chamber and etching the substrate by cyclically performing a periodic plasma process. The periodic plasma process includes applying, in a first phase, a first SP pulse to an SP coupling element to generate plasma within the processing chamber while applying a first HBP pulse to the substrate holder to etch the substrate. An RF of the first SP pulse is greater than an RF of the first HBP pulse. The periodic plasma process includes applying, in a second phase, an LBP pulse to the substrate holder, the LBP pulse being coupled to the substrate holder while applying a second SP pulse to the SP coupling element and without coupling an HBP pulse to the substrate holder to concurrently etch the substrate and deposit passivating species on the substrate. An RF of the LBP pulse is less than an RF of the first HBP pulse. The periodic plasma process includes applying, in a third phase, a second HBP pulse to the substrate holder while applying a third SP pulse to the SP coupling element to deposit passivating species on the substrate. An RF of the second HBP pulse is greater than the RF of the LBP pulse, and a power level of the third SP pulse is less than a power level of the first SP pulse and less than a power level of the second SP pulse.

Example 9. The method of Example 8, where: the first phase has a first duration, the second phase has a second duration, and the third phase has a third duration; and two or more of the first duration, the second duration, and the third duration are different within a single cycle of the periodic plasma process.

Example 10. The method of Example 8, where: the first phase has a first duration, the second phase has a second duration, and the third phase has a third duration; and the first duration, the second duration, and the third duration are a same duration within a single cycle of the periodic plasma process.

Example 11. The method of any one of Examples 8-10, where: within each cycle of the periodic plasma process, the first phase has a first duration, the second phase has a second duration, and the third phase has a third duration; and at least two of the first duration, the second duration, and the third duration have different corresponding durations in a first cycle than in a second cycle.

Example 12. The method of any one of Examples 8-11, where: within each cycle of the periodic plasma process, the first phase has a first duty cycle, the second phase has a second duty cycle, and the third phase has a third duty cycle; and at least two of the first, second, and third phases have different corresponding duty cycles in a first cycle than in a second cycle.

Example 13. The method of any one of Examples 8-12, where: the first phase is an etch phase, the second phase is an etch-and-deposition phase, and the third phase is a deposition phase; in a first cycle of the periodic plasma process, a duty cycle of a combination of the etch phase and the etch-and-deposition phase is greater than 50% of a period of the periodic plasma process, and a duty cycle of the etch phase is greater than a duty cycle of the deposition phase; and in a second cycle of the periodic plasma process, a duty cycle of a combination of the deposition phase and the etch-and-deposition phase is greater than 50% of the period of the periodic plasma process, and a duty cycle of the deposition phase is greater than a duty cycle of the etch phase.

Example 14. The method of any one of Examples 8-13, where, in a third cycle of the periodic plasma process, a duty cycle of the etch phase, a duty cycle of the etch-and-deposition phase, and a duty cycle of the deposition phase are equal.

Example 15. The method of any one of Examples 8-14, where the power level of the first SP pulse and the power level of the second SP pulse are substantially equal.

Example 16. The method of any one of Examples 8-15, where: the RF of the LBP pulse is less than 2 MHz; and the RF of the first HBP and the RF of the second HBP are in a range from 3 MHz to 30 MHz.

Example 17. The method of any one of Examples 8-16, where a power level of the LBP pulse is less than 100 W; power levels of the first and second HBP pulses are greater than the power level of the LBP pulse; and a power level of the SP pulse is between the power level of the LBP pulse and the power levels of the first HBP pulse and the second HBP pulse.

Example 18. The method of any one of Examples 8-17, where the power levels of the first and second HBP pulses are at least three times the power level of the LBP pulse.

Example 19. The method of any one of Examples 8-18, where a period of the periodic plasma process is between about 1 ms and about 100 ms

Example 20. The method of any one of Examples 8-19, including performing a first cycle and a second cycle of the periodic plasma process and, for the second cycle of the periodic plasma process, adjusting at least one of: a power level of the SP pulse, the LBP pulse, the first HBP, or the second HBP; a duty cycle of the first phase, the second phase, or the third phase; and a duration of the first phase, the second phase, or the third phase.

Example 21. A method includes positioning a semiconductor substrate in a processing chamber of a plasma tool. The semiconductor substrate includes a film stack having first layers of a first material and second layers of a second material in an alternating stacked arrangement. The film stack includes a recess that exposes sidewall surfaces of the first and second layers in the recess, and an inner spacer structure is located on the sidewall surfaces of the first and second layers and on a bottom surface of the recess. The method includes etching the inner spacer structure by cyclically performing a periodic plasma process that comprises multiple multiphase pulse cycles. Each multiphase pulse cycle includes generating, in a first phase, a plasma by applying an SP to the processing chamber, the plasma etching the inner spacer structure at a first etch rate; generating, in a second phase, low-energy ions by concurrently applying the SP and an LBP to the processing chamber, the plasma etching the inner spacer structure at a second etch rate while the low-energy ions passivate on exposed surfaces of the film stack; and generating, in a third phase, high-energy ions by concurrently applying the SP and an HBP to the processing chamber, the high-energy ions passivating on the bottom surface of the recess. A same gas combination may be supplied to the processing chamber during each multiphase pulse cycle of the multiple multiphase pulse cycles.

Example 22. The method of Example 21, where at least a portion of the sidewall surfaces of the second layers are recessed relative to the sidewall surfaces of adjacent first layers such that indents are formed in the film stack at the first layers, the inner spacer structure extending into the indents.

Example 23. The method of any one of Examples 21-22, where the first material is silicon and the second material is silicon-germanium, or the first material is silicon-germanium and the second material is silicon.

Example 24. The method of any one of Examples 21-23, where the inner spacer structure includes SiN, SiON, or SiₓO_{y}C_{z}N.

Example 25. The method of any one of Examples 21-24, further including terminating execution of the periodic plasma process in response to: the inner space structure on the sidewall surfaces of the first layers and the second layers reaches being desired thickness; a predetermined number of cycles being executed; or the inner spacer structure being fully removed from the sidewall surfaces of the first layers and the second layers.

Example 26. The method of any one of Examples 21-25, where, following terminating execution of the periodic process, at least a portion of the inner spacer structure remains on the bottom surface of the recess.

Example 27. The method of any one of Examples 21-26, where the first etch rate is greater than the second etch rate.

Example 28. The method of any one of Examples 21-27, including applying the SP to the processing chamber in the second phase at a same power level as the SP is applied to the processing chamber in the first phase.

Example 29. The method of any one of Examples 21-28, including applying the SP to the processing chamber in the third phase at a lower power level than the SP is applied to the processing chamber in the first phase and the second phase.

Example 30. The method of any one of Examples 21-29, where: the gas combination includes an etchant gas that includes fluorocarbon or hydrofluorocarbon, and a carrier gas; an etch species includes fluorine dissociated from the etchant gas; and the low-energy ions and high-energy ions comprise CF+.

Example 31. The method of any one of Examples 21-30, where etching the inner spacer structure by cyclically performing the periodic plasma process includes adjusting, from a first multiphase pulse cycle of the multiple multiphase pulse cycles to a second multiphase pulse cycle of the multiple multiphase pulse cycles, at least one plasma process parameter, the at least one plasma process parameter being: a duration of the first phase, the second phase, or the third phase; a power level of the SP, the LBP, or the HBP from the first phase, the second phase, or the third phase of the first multiphase pulse cycle to the first phase, the second phase, or the third phase of the second multiphase pulse cycle; a duty cycle of the first phase, the second phase, or the third phase; or an execution order of the first phase, the second phase, and the third phase from the first multiphase pulse cycle to the second multiphase pulse cycle.

Example 32. The method of any one of Examples 21-31, where: the semiconductor substrate includes, prior to the semiconductor substrate being positioned in the processing chamber, the film stack having the first layers and the second layers in the alternating stacked arrangement, including the recess that exposes the sidewall surfaces of the first and second layers in the recess, and the inner spacer structure located on the sidewall surfaces of the first and second layers and on the bottom surface of the recess; or one or more of the film stack having the first layers and the second layers in the alternating stacked arrangement, the recess that exposes the sidewall surfaces of the first and second layers in the recess, or the inner spacer structure located on the sidewall surfaces of the first and second layers and on the bottom surface of the recess are formed on the semiconductor substrate after positioning the semiconductor substrate in the processing chamber but prior to etching the inner spacer structure by cyclically performing the periodic plasma process.

“Substrate,” “target substrate,” “structure,” or “device” as used herein generically refers to an object being processed in accordance with the invention, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method, comprising:
positioning a substrate on a substrate holder in a processing chamber; and
etching the substrate by cyclically performing a periodic plasma process that comprises multiple multiphase pulse cycles that each comprises:
an elevated etching phase that comprises applying a source power (SP) to the processing chamber at a first SP level;
an etching-and-deposition phase that comprises applying the SP to the processing chamber at a second SP level and applying a lower-frequency radio frequency (RF) bias power (LBP) to the processing chamber at a first LBP level; and
an elevated deposition phase that comprises applying the SP to the processing chamber at a third SP level and applying a higher-frequency RF bias power (HBP) to the processing chamber at a first HBP level, the third SP level being less than the first SP level;
wherein a same gas combination is supplied to the processing chamber during each multiphase pulse cycle of the multiple multiphase pulse cycles.

2. The method of claim 1, wherein etching the substrate by cyclically performing the periodic plasma process comprises adjusting, from a first multiphase pulse cycle of the multiple multiphase pulse cycles to a second multiphase pulse cycle of the multiple multiphase pulse cycles, at least one plasma process parameter, the at least one plasma process parameter being:
a duration of the elevated etching phase, the etching-and-deposition phase, or the elevated deposition phase;
a power level of the SP, the LBP, or the HBP from the elevated etching phase, the etching-and-deposition phase, or the elevated deposition phase of the first multiphase pulse cycle to the elevated etching phase, the etching-and-deposition phase, or the elevated deposition phase of the second multiphase pulse cycle;
a duty cycle of the elevated etching phase, the etching-and-deposition phase, or the elevated deposition phase; or
an execution order of the elevated etching phase, the etching-and-deposition phase, and the elevated deposition phase from the first multiphase pulse cycle to the second multiphase pulse cycle.

3. The method of claim 2, wherein:
the method further comprises determining, during the periodic plasma process, in-situ measurements associated with the periodic plasma process; and
adjusting, from the first multiphase pulse cycle to the second multiphase pulse cycle, the at least one plasma process parameter comprises adjusting the at least one plasma process parameter in situ according to the in-situ measurements.

4. The method of claim 2, wherein adjusting, from the first multiphase pulse cycle to the second multiphase pulse cycle, the at least one plasma process parameter comprises adjusting the at least one plasma process parameter according to a predetermined recipe, the predetermined recipe being determined prior to performing the periodic plasma process.

5. The method of claim 1, wherein the elevated etching phase of a first multiphase pulse cycle of the multiple multiphase pulse cycles comprises, concurrently with applying the SP to the processing chamber at the first SP level, applying the HBP to the processing chamber at a second HBP level, the second HBP level being less than the first HBP level.

6. The method of claim 1, wherein:
each multiphase pulse cycle of the multiple multiphase pulse cycles is performed continuously or stepwise; and
each cycle of the periodic plasma process is performed continuously or stepwise with respect to a prior or subsequent cycle of the periodic plasma process.

7. A method, comprising:
positioning a substrate on a substrate holder in a processing chamber;
etching the substrate by cyclically performing a periodic plasma process, the periodic plasma process comprising:
applying, in a first phase, a first source power (SP) pulse to an SP coupling element to generate plasma within the processing chamber while applying a first higher-frequency radio frequency (RF) bias power (HBP) pulse to the substrate holder to etch the substrate, an RF of the first SP pulse being greater than an RF of the first HBP pulse;
applying, in a second phase, a lower-frequency RF bias power (LBP) pulse to the substrate holder, the LBP pulse being coupled to the substrate holder while applying a second SP pulse to the SP coupling element and without coupling an HBP pulse to the substrate holder to concurrently etch the substrate and deposit passivating species on the substrate, an RF of the LBP pulse being less than an RF of the first HBP pulse; and
applying, in a third phase, a second HBP pulse to the substrate holder while applying a third SP pulse to the SP coupling element to deposit passivating species on the substrate, an RF of the second HBP pulse being greater than the RF of the LBP pulse, and a power level of the third SP pulse being less than a power level of the first SP pulse and less than a power level of the second SP pulse.

8. The method of claim 7, wherein:
within each cycle of the periodic plasma process, the first phase has a first duty cycle, the second phase has a second duty cycle, and the third phase has a third duty cycle; and
at least two of the first phase, the second phase, and the third phase have different corresponding duty cycles in a first cycle than in a second cycle.

9. The method of claim 7, wherein:
the first phase is an etch phase, the second phase is an etch-and-deposition phase, and the third phase is a deposition phase;
in a first cycle of the periodic plasma process, a duty cycle of a combination of the etch phase and the etch-and-deposition phase is greater than 50% of a period of the periodic plasma process, and a duty cycle of the etch phase is greater than a duty cycle of the deposition phase; and
in a second cycle of the periodic plasma process, a duty cycle of a combination of the deposition phase and the etch-and-deposition phase is greater than 50% of the period of the periodic plasma process, and a duty cycle of the deposition phase is greater than a duty cycle of the etch phase.

10. The method of claim 9, wherein, in a third cycle of the periodic plasma process, a duty cycle of the etch phase, a duty cycle of the etch-and-deposition phase, and a duty cycle of the deposition phase are equal.

11. The method of claim 7, wherein the power level of the first SP pulse and the power level of the second SP pulse are substantially equal.

12. The method of claim 7, wherein:
the RF of the LBP pulse is less than 2 MHz;
the RF of the first HBP and the RF of the second HBP are in a range from 3 MHz to 30 MHz;
a power level of the LBP pulse is less than 100 W;
power levels of the first HBP pulse and the second HBP pulse are greater than the power level of the LBP pulse; and
a power level of the SP pulse is between the power level of the LBP pulse and the power levels of the first HBP pulse and the second HBP pulse.

13. The method of claim 7, comprising performing a first cycle and a second cycle of the periodic plasma process, and, for the second cycle of the periodic plasma process, adjusting at least one of:
a power level of the SP pulse, the LBP pulse, the first HBP, or the second HBP;
a duty cycle of the first phase, the second phase, or the third phase; and
a duration of the first phase, the second phase, or the third phase.

14. A method, comprising:
positioning a semiconductor substrate in a processing chamber of a plasma tool, the semiconductor substrate comprising a film stack having first layers of a first material and second layers of a second material in an alternating stacked arrangement, the film stack comprising a recess that exposes sidewall surfaces of the first and second layers in the recess, an inner spacer structure being located on the sidewall surfaces of the first and second layers and on a bottom surface of the recess;
etching the inner spacer structure by cyclically performing a periodic plasma process that comprises multiple multiphase pulse cycles that each comprises:
generating, in a first phase, a plasma by applying a source power (SP) to the processing chamber, the plasma etching the inner spacer structure at a first etch rate;
generating, in a second phase, low-energy ions by concurrently applying the SP and a lower-frequency radio frequency (RF) bias power (LBP) to the processing chamber, the plasma etching the inner spacer structure at a second etch rate while the low-energy ions passivate on exposed surfaces of the film stack; and
generating, in a third phase, high-energy ions by concurrently applying the SP and a higher-frequency RF bias power (HBP) to the processing chamber, the high-energy ions passivating on the bottom surface of the recess;
wherein a same gas combination is supplied to the processing chamber during each multiphase pulse cycle of the multiple multiphase pulse cycles.

15. The method of claim 14, wherein:
at least a portion of the sidewall surfaces of the second layers are recessed relative to the sidewall surfaces of adjacent first layers such that indents are formed in the film stack at the first layers, the inner spacer structure extending into the indents;
the first material is silicon and the second material is silicon-germanium, or the first material is silicon-germanium and the second material is silicon; and
the inner spacer structure comprises:
silicon nitride (SiN);
silicon oxynitride (SiON); or
silicon oxycarbonitride (SiₓO_{y}C_{z}N).

16. The method of claim 14, further comprising terminating execution of the periodic plasma process in response to:
the inner space structure on the sidewall surfaces of the first layers and the second layers reaches being desired thickness;
a predetermined number of cycles being executed; or
the inner spacer structure being fully removed from the sidewall surfaces of the first layers and the second layers.

17. The method of claim 16, wherein, following terminating execution of the periodic process, at least a portion of the inner spacer structure remains on the bottom surface of the recess.

18. The method of claim 14, wherein:
the first etch rate is greater than the second etch rate; and
the method comprises:
applying the SP to the processing chamber in the second phase at a same power level as the SP is applied to the processing chamber in the first phase; and
applying the SP to the processing chamber in the third phase at a lower power level than the SP is applied to the processing chamber in the first phase and the second phase.

19. The method of claim 14, wherein:
the gas combination comprises:
an etchant gas that comprises fluorocarbon or hydrofluorocarbon; and
a carrier gas;
an etch species comprises fluorine dissociated from the etchant gas; and
the low-energy ions and high-energy ions comprise CF+.

20. The method of claim 14, wherein etching the inner spacer structure by cyclically performing the periodic plasma process comprises adjusting, from a first multiphase pulse cycle of the multiple multiphase pulse cycles to a second multiphase pulse cycle of the multiple multiphase pulse cycles, at least one plasma process parameter, the at least one plasma process parameter being:
a duration of the first phase, the second phase, or the third phase;
a power level of the SP, the LBP, or the HBP from the first phase, the second phase, or the third phase of the first multiphase pulse cycle to the first phase, the second phase, or the third phase of the second multiphase pulse cycle;
a duty cycle of the first phase, the second phase, or the third phase; or
an execution order of the first phase, the second phase, and the third phase from the first multiphase pulse cycle to the second multiphase pulse cycle.
